(19) United States
(12) Patent Application Publication
(10) Pub. No.: US 2016/0211431 A1
(43) Pub. Date: Jul. 21, 2016

(54) HEAT RADIATION SHEET, LIGHT EMITTING DEVICE, AND HEAT RADIATION BACK SHEET FOR PHOTOVOLTAIC MODULE, EACH INCLUDING BORON NITRIDE HEAT DISSIPATION LAYER

(71) Applicant: KOREA INSTITUTE OF SCIENCE AND TECHNOLOGY, Seoul (KR)

(72) Inventors: Cheol Min YANG, Bongdong-eup (KR); Seung Yong LEE, Bongdong-eup (KR)

(21) Appl. No.: 14/995,612

(22) Filed: Jan. 14, 2016

(30) Foreign Application Priority Data
Jan. 21, 2015 (KR) 10-2015-0010031
Jan. 21, 2015 (KR) 10-2015-0010032
Feb. 6, 2015 (KR) 10-2015-0018890

(51) Int. Cl. H01L 33/64; F28F 13/18; F28F 21/00; H01L 31/024

(52) U.S. Cl. CPC H01L 33/641; H01L 31/024; F28F 13/18; F28F 21/00

(57) ABSTRACT

Provided are a heat radiation sheet including a heat-absorbing support and a heat dissipation layer formed on at least one surface of the heat-absorbing support and including a boron nitride (BN) layer, a substrate for a light emitting device that includes an inorganic support and a BN pattern layer formed on the inorganic support, a light emitting device using the substrate, a back sheet including a heat dissipation layer including a metal layer and first and second BN layers respectively formed on upper and lower surfaces of the metal layer, and a photovoltaic module including the back sheet. The heat radiation sheet, the substrate, the light emitting device, the back sheet, and the photovoltaic module include the BN layer and thus exhibit excellent heat radiation characteristics and/or excellent luminous characteristics.

### CROSS-REFERENCE TO RELATED APPLICATIONS

This application claims the benefit of Korean Patent Application No. 10-2015-0010031, filed on Jan. 21, 2015, Korean Patent Application No. 10-2015-0010032, filed on Jan. 21, 2015, and Korean Patent Application No. 10-2015-0018890, filed on Feb. 6, 2015, in the Korean Intellectual Property Office, the disclosures of which are incorporated herein in their entirety by reference.

### BACKGROUND

1. Field

One or more exemplary embodiments relate to a heat radiation sheet, a light emitting device, and a heat radiation back sheet for a photovoltaic module, each of which includes a boron nitride (BN) heat dissipation layer, and more particularly, to a heat radiation sheet including a BN heat dissipation layer and thus exhibiting enhanced heat radiation characteristics, a light emitting device including a substrate including a BN heat radiation pattern layer and thus exhibiting enhanced luminous characteristics, and a heat radiation back sheet for photovoltaic modules that includes a BN heat dissipation layer and thus performance deterioration of photovoltaic modules due to heating by direct sunlight and waste heat generated during photovoltaic conversion may be effectively prevented.

2. Description of the Related Art

Recently, heat radiation sheets are widely used to radiate, to the outside, heat generated from electronic devices and optical devices. Heat generated from the inside of a device deteriorates operating stability of the devices and thus shortens the lifespan thereof. In addition, the operating reliability of devices is closely related to heat dissipation and thus it is very important to radiate heat generated from a device to the outside. Therefore, various heat radiation materials have been developed and the development of heat radiation sheets using the same is actively underway.

Examples of heat radiation sheets, currently being developed, include a graphite compression sheet, a polymer/ceramic composite sheet, a multilayer coating metal thin film sheet, and the like. However, the graphite compression sheet exhibits excellent heat radiation in a horizontal direction, while exhibiting very poor heat radiation in a vertical direction. In addition, interlayer separation easily occurs and thus the graphite compression sheet has poor durability. The polymer/ceramic composite sheet has limitations due to low thermal conductivity of a general polymer material. The multilayer coating metal thin film sheet has low heat radiation efficiency in a horizontal direction. Therefore, there is an urgent need to develop a heat radiation sheet having high heat radiation performance both in a horizontal direction and in a vertical direction as well as high durability.

Meanwhile, there are generally two methods of reducing power loss and enhancing efficiency by enhancing heat radiation from light emitting devices. The first method is to enhance heat radiation by attaching a heat dissipation plate or a heat dissipation tape to the outside of a light emitting device, which is currently mostly widely used. The second method is to enhance heat dissipation inside a light emitting device. For example, this method includes an attempt to manufacture vertical-type light emitting devices, to install a graphene layer or a reflective mirror layer, and the like.

However, in the first method, the volume of a light emitting device increases due to the attachment of a heat dissipation plate or a heat dissipation tape to the outside of the light emitting device and thus it is difficult to apply this method to thin light emitting devices. In addition, the operating performances of light emitting devices may dramatically deteriorate due to seepage of moisture such as rainwater, and the like, which may significantly deteriorate the efficiencies of light emitting devices. In vertical-type light emitting devices manufactured in the second method, a metal electrode is formed after separation of a sapphire substrate with very low thermal conductivity used for the growth of a gallium nitride (GaN) substrate, by using laser beams, which is a very complicated and cost-consuming process. In addition, a method of inserting a graphene layer or a reflective mirror layer into a light emitting device is also complicated and such layers have very high electrical conductivity, which may cause problems to the operating of light emitting devices.

Meanwhile, photovoltaic modules and inverters play a very critical role in producing and using electrical energy by using photovoltaic energy. In particular, photovoltaic modules, which generate electricity by directly receiving sunlight, are important. A photovoltaic cell is a minimum unit of a photovoltaic battery and, in real life, a plurality of photovoltaic cells is connected in series and/or in parallel. The photovoltaic cells connected in series and/or in parallel are mainly used outdoors and thus may be subjected to various harsh environments. Therefore, there is a need to use an apparatus for protecting photovoltaic cells connected to one another. For this, a photovoltaic module type including a plurality of photovoltaic cells packaged therein is used.

In general, a photovoltaic module includes photovoltaic cells, upper and lower encapsulation layers respectively attached to upper and lower surfaces of the photovoltaic cells, a surface layer (glass) attached to the upper encapsulation layer, and a back sheet attached to the lower encapsulation layer.

However, in a general photovoltaic module, all members constituting the module are encapsulated and have low thermal conductivity and a back sheet installed at the rearmost of the module is not configured so as to smoothly radiate heat to the outside. Due to this, heat generated from the inside of a photovoltaic module is difficult to rapidly radiate to the outside and thus degradation of the module occurs, which deteriorates the performance of the module and, consequently, the lifespan and reliability of the photovoltaic module significantly deteriorate.

General back sheets for photovoltaic modules are manufactured based on stacked films fabricated by appropriately stacking, by using an adhesive, a plurality of films selected from a fluorinated resin film, a polyester film, a polyolefin film, and a film formed of a polyolefin-based copolymer such as ethylene-vinyl acetate (EVA). However, a back sheet consisting of such stacked polymer films has a low thermal conductivity, e.g., about 0.2 W/mK. In this regard, heat radiation performance is disregarded and the operating reliability of photovoltaic modules is only taken into consideration. Due to this, heat is difficult to be effectively radiated to the outside from a back sheet installed at the rearmost of a photovoltaic module, which is a major cause of a decrease in power generation of photovoltaic modules.

To address such low heat radiation performance problems, Korean Patent Registration No. 0999460 discloses a technology of forming a covering layer at a sheet formed of a metal such as aluminum, copper, stainless steel, or the like and then attaching the resulting structure to a photovoltaic module by using a double-sided tape or an adhesive. However, heat radiation sheets using metal materials are easily corroded by moisture in high-temperature and high-humidity areas. Korean Patent Registration No. 1362965 discloses a back sheet using a graphene-based material with excellent heat radiation properties. However, such a graphene sheet also has excellent electrical properties and thus a post-treatment process, i.e., coating treatment, is further needed.

### SUMMARY

One or more exemplary embodiments include heat radiation sheets that are manufactured using a simple process and have excellent heat radiation performance both in a horizontal direction and in a vertical direction as well as high durability.

One or more exemplary embodiments include substrates manufactured using a simple process and including a heat dissipation pattern layer that may enhance luminous characteristics of light emitting devices, and light emitting devices with enhanced luminous characteristics by including the substrates.

One or more exemplary embodiments include back sheets for photovoltaic modules that exhibit electrically insulating characteristics, high heat radiation performances both in a horizontal direction and in a vertical direction, as well as high durability, and photovoltaic modules including the back sheets.

Additional aspects will be set forth in part in the description which follows and, in part, will be apparent from the description, or may be learned by practice of the presented embodiments.

According to one or more exemplary embodiments, a heat radiation sheet includes a heat-absorbing support, and a heat dissipation layer formed on at least one surface of the heat-absorbing support and including a boron nitride (BN) layer.

The heat-absorbing support may include a material selected from the group consisting of a metal, a metal oxide, a metal nitride, a metal carbide, and a carbonaceous material.

The metal may include a material selected from the group consisting of tungsten, titanium, iron, copper, nickel, silver, zinc, molybdenum, and an alloy including at least one of these metals.

The metal oxide may include a material selected from the group consisting of indium oxide, zinc oxide, zinc indium oxide, magnesium oxide, aluminum oxide, silicon oxide, and zirconium oxide.

The metal nitride may include a material selected from the group consisting of boron nitride, aluminum nitride, and silicon nitride.

The metal carbide may include a material selected from the group consisting of silicon carbide, boron carbide, aluminum carbide, magnesium carbide, beryllium carbide, titanium carbide, tungsten carbide, vanadium carbide, niobium carbide, chromium carbide, molybdenum carbide.

The carbonaceous material may include a material selected from the group consisting of a graphite, a carbon nanotube, a carbon fiber, a carbon nanofiber, graphene, and silicon carbide (SiC).

The heat-absorbing support may be in the form of a plate, a wafer, a film, or a mesh.

The heat-absorbing support may have a thickness of about 10 μm to about 1,000 μm, and the BN layer may have a thickness of about 5 μm to about 500 μm.

According to one or more exemplary embodiments, a method of manufacturing a heat radiation sheet includes preparing a heat-absorbing support, forming a carbon-containing organic or inorganic precursor layer on at least one surface of the heat-absorbing support, and converting the carbon-containing organic or inorganic precursor layer into a BN layer by heat-treating the heat-absorbing support with the carbon-containing organic or inorganic precursor layer formed thereon in a nitrogen-containing gas atmosphere and in the presence of a boron-containing compound.

The carbon-containing organic or inorganic precursor layer may be formed by spin coating, dip coating, spray coating, roll coating, gravure coating, comma coating, die coating, or vapor deposition.

The heat-treating may be performed at a temperature ranging from about 1,000° C. to about 2,000° C. and a pressure of about 1×10¹ Pa to about 1.013×10⁵ Pa at a nitrogen-containing gas flow rate of about 0.5 L/min to about 10 L/min for about 1 hr to about 10 hrs.

The carbon-containing organic precursor may be a carbon-containing organic polymer.

The carbon-containing inorganic precursor may be selected from graphite, a carbon nanotube, a carbon fiber, graphene, graphene oxide, activated carbon, and carbon black.

According to one or more exemplary embodiments, a substrate for a light emitting device includes an inorganic support and a BN pattern layer formed on the inorganic support.

An area ratio of the BN pattern layer to the inorganic support may be in the range of about 20% to about 80%.

According to one or more exemplary embodiments, a method of manufacturing a substrate for a light emitting device includes preparing an inorganic support, forming a carbon-containing organic or inorganic precursor pattern layer on the inorganic support, and converting the carbon-containing organic or inorganic precursor pattern layer into a BN pattern layer by heat-treating the inorganic support with the carbon-containing organic or inorganic precursor pattern layer formed thereon in a nitrogen-containing gas atmosphere and in the presence of a boron-containing compound.

The forming of the carbon-containing organic or inorganic precursor pattern layer may include forming a carbon-containing organic or inorganic precursor layer to cover the entire surface of the inorganic support and partially removing the carbon-containing organic or inorganic precursor layer by photolithography techniques.

The carbon-containing organic or inorganic precursor layer may be formed by spin coating, dip coating, spray coating, or vapor deposition.

The partially removing of the carbon-containing organic or inorganic precursor layer may be performed by wet etching or dry etching in such a manner that an area ratio of the carbon-containing organic or inorganic precursor pattern layer to the inorganic support is in a range of about 20% to about 80%.

The heat-treating method is not particularly limited so long as it enables the carbon-containing organic or inorganic precursor pattern layer to be converted into a BN pattern layer. The heat-treating may be performed at a temperature ranging from about 1,000° C. to about 2,000° C. and a pressure of about 1×10¹ Pa to about 1.013×10⁵ Pa at a nitrogen-containing gas flow rate of about 0.5 L/min to about 10 L/min for about 1 hr to about 10 hrs.

The inorganic support may include a material selected from sapphire (Al₂O₃), silicon (Si), silicon carbide (SiC), gallium nitride (GaN), germanium (Ge), gallium arsenide (GaAs), zinc oxide (ZnO), silicon germanium (SiGe), gallium oxide (Ga₂O₃), lithium gallium oxide (LiGaO₂), lithium aluminum oxide (LiAlO₂), and magnesium aluminum oxide (MgAl₂O₄).

The carbon-containing organic precursor is not particularly limited so long as it is a carbon-containing organic polymer, and the carbon-containing inorganic precursor may be a carbon-containing inorganic material selected from graphite, graphene, graphene oxide, activated carbon, a carbon nanotube, and carbon black.

According to one or more exemplary embodiments, a light emitting device includes a substrate including an inorganic support and a BN pattern layer formed on the inorganic support, a first conductive type semiconductor layer formed on the BN pattern layer, an active layer formed on the first conductive type semiconductor layer, a second conductive type semiconductor layer formed on the active layer, a first electrode formed on the first conductive type semiconductor layer, and a second electrode formed on the second conductive type semiconductor layer.

In this regard, the first conductive type semiconductor layer may be an n-type semiconductor layer, and the second conductive type semiconductor layer may be a p-type semiconductor layer. For example, the inorganic support may be sapphire (Al₂O₃) support, the n-type semiconductor layer may be an n-type GaN layer, and the p-type semiconductor layer may be a p-type GaN layer. The light emitting device may further include a buffer layer to cover and planarize the BN pattern layer. For example, the buffer layer may be an undoped GaN layer that is not doped with an impurity.

The light emitting device may further include an ohmic contact layer formed on the second conductive type semiconductor layer. In this regard, the second electrode may be formed on a partial area of the ohmic contact layer.

According to one or more exemplary embodiments, a method of manufacturing a light emitting device includes providing a substrate including an inorganic support and a BN pattern layer formed on the inorganic support, forming a first conductive type semiconductor layer on the BN pattern layer to cover the BN pattern layer, forming an active layer on the first conductive type semiconductor layer, forming a second conductive type semiconductor layer on the active layer, forming a first electrode on a partial area of the first conductive type semiconductor layer, and forming a second electrode on a partial area of the second conductive type semiconductor layer.

The method of manufacturing a light emitting device may optionally further include forming a buffer layer so as to cover and planarize the BN pattern layer before the forming of the first conductive type semiconductor layer.

In another exemplary embodiment, the method of manufacturing a light emitting device may further include forming an ohmic contact layer on the second conductive type semiconductor layer before the forming of the first electrode. In this regard, the first electrode may be formed on a partial area of the first conductive type semiconductor layer, and the second electrode may be formed on a partial area of the ohmic contact layer.

According to one or more exemplary embodiments, a back sheet for a photovoltaic module includes a heat dissipation layer including a metal layer, a first BN layer formed on a lower surface of the metal layer, and a second BN layer formed on an upper surface of the metal layer, a protective layer formed on one surface of the heat dissipation layer, and an adhesive layer to adhere the protective layer to the heat dissipation layer.

According to one or more exemplary embodiments, a photovoltaic module includes a photovoltaic cell, upper and lower encapsulation layers respectively attached to upper and lower surfaces of the photovoltaic cell, and an upper surface layer attached to the upper encapsulation layer and a back sheet attached to the lower encapsulation layer, wherein the back sheet includes a heat dissipation layer including a metal layer, a first BN layer formed on a lower surface of the metal layer, and a second BN layer formed on an upper surface of the metal layer, a protective layer formed on one surface of the heat dissipation layer, and an adhesive layer to adhere the protective layer to the heat dissipation layer.

The metal layer may include a material selected from the group consisting of tungsten, titanium, iron, copper, nickel, silver, zinc, molybdenum, and an alloy including at least one of these metals.

The metal layer may have a thickness of about 10 μm to about 1,000 μm, and the BN layer may have a thickness of about 5 μm to about 500 μm.

The protective layer may include a film selected from the group consisting of a fluorinated resin film, a polyester film, a polyolefin film, and a polyolefin-based copolymer film.

The protective layer may include a film selected from the group consisting of a polyvinylidene fluoride (PVDF) film, a polyethylene terephthalate (PET) film, a polyethylene (PE) film, a polypropylene (PP) film, and an ethylene-vinyl acetate (EVA) film.

In the photovoltaic module, the upper and lower encapsulation layers may include an EVA layer, and the surface layer may include a glass layer.

According to one or more exemplary embodiments, a method of manufacturing a back sheet for a photovoltaic module includes forming carbon-containing organic or inorganic precursor layers on both of the opposite surfaces of a metal layer, converting the carbon-containing organic or inorganic precursor layers into BN layers by heat-treating the metal layer with the carbon-containing organic or inorganic precursor layers formed on both of the opposite surfaces thereof in a nitrogen-containing gas atmosphere and in the presence of a boron-containing compound to complete the formation of a heat dissipation layer including first and second BN layers formed on both of the opposite surfaces of the metal layer, and attaching a protective layer to one surface of the heat dissipation layer by an adhesive layer therebetween.

The carbon-containing organic or inorganic precursor layers may be formed by spin coating, dip coating, spray coating, roll coating, gravure coating, comma coating, die coating, or vapor deposition.

The heat-treating may be performed at a temperature ranging from about 1,000° C. to about 2,000° C. and a pressure of about 1×10¹ Pa to about 1.013×10⁵ Pa at a nitrogen-containing gas flow rate of about 0.5 L/min to about 10 L/min for about 1 hr to about 10 hrs.

The carbon-containing organic precursor may be a carbon-containing organic polymer.

The carbon-containing inorganic precursor may be selected from graphite, a carbon nanotube, a carbon fiber, graphene, graphene oxide, amorphous carbon, and carbon black.

### BRIEF DESCRIPTION OF THE DRAWINGS

These and/or other aspects will become apparent and more readily appreciated from the following description of the embodiments, taken in conjunction with the accompanying drawings in which:

FIG. 1 is a side cross-sectional view of a heat radiation sheet according to an exemplary embodiment;

FIG. 2 is a side cross-sectional view of a heat radiation sheet according to another exemplary embodiment;

FIG. 3 illustrates Raman spectroscopy analysis results of a surface of a boron nitride (BN) heat dissipation layer grown on a heat-absorbing support of the heat radiation sheet of FIG. 1;

FIG. 4 is a scanning electron microscope (SEM) image of the BN heat dissipation layer grown on the heat-absorbing layer of the heat radiation sheet of FIG. 1;

FIG. 5 is a side cross-sectional view of a substrate for a light emitting device according to an exemplary embodiment;

FIGS. 6 to 10 are side cross-sectional views sequentially illustrating a process of manufacturing a light emitting device using the substrate illustrated in FIG. 5;

FIG. 11 is a perspective view of a photovoltaic module according to an exemplary embodiment;

FIG. 12 is a cross-sectional view taken along a line A-A′ of FIG. 11; and

FIG. 13 is a cross-sectional view particularly illustrating a stacked structure of a back sheet for the photovoltaic module illustrated in FIGS. 11 and 12.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the exemplary embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

First, heat radiation sheets including boron nitride (BN) heat dissipation layers, according to exemplary embodiments, and methods of manufacturing the same will be described with reference to the accompanying drawings.

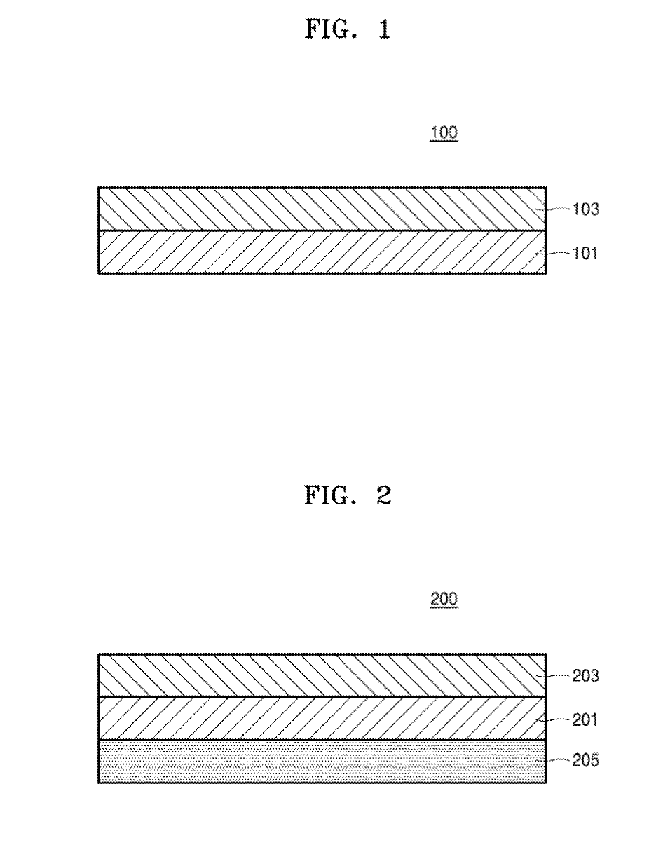

FIG. 1 is a side cross-sectional view of a heat radiation sheet 100 according to an exemplary embodiment. Referring to FIG. 1, the heat radiation sheet 100 includes a heat-absorbing support 101 and a heat dissipation layer 103 including a BN layer, formed on one surface of the heat-absorbing support 101.

FIG. 2 is a side cross-sectional view of a heat radiation sheet 200 according to another exemplary embodiment. Referring to FIG. 2, the heat radiation sheet 200 includes a heat-absorbing support 201, an upper heat dissipation layer 203 formed on a upper portion of the heat-absorbing support 201, and a lower heat dissipation layer 205 formed on a lower portion of the heat-absorbing support 201.

The heat-absorbing support may include a material selected from the group consisting of a metal, a metal oxide, a metal nitride, a metal carbide, and a carbonaceous material.

The metal may include a material selected from the group consisting of tungsten, titanium, iron, copper, nickel, silver, zinc, molybdenum, and an alloy including at least one of these metals.

The metal oxide may include a material selected from the group consisting of indium oxide, zinc oxide, zinc indium oxide, magnesium oxide, aluminum oxide, silicon oxide, and zirconium oxide.

The metal nitride may include a material selected from the group consisting of boron nitride, aluminum nitride, and silicon nitride.

The metal carbide may include a material selected from the group consisting of silicon carbide, boron carbide, aluminum carbide, magnesium carbide, beryllium carbide, titanium carbide, tungsten carbide, vanadium carbide, niobium carbide, chromium carbide, molybdenum carbide.

The carbonaceous material may include a material selected from the group consisting of graphite, a carbon nanotube, a carbon fiber, a carbon nanofiber, graphene, and silicon carbide (SiC).

As described in detail above, in the heat radiation sheet, the BN heat dissipation layer is formed by performing heat treatment of a carbon-containing organic or inorganic precursor layer to be converted into a BN layer. Taking into consideration the fact that the heat treatment process is generally performed at a temperature ranging from about 1,000° C. to about 2,000° C., it is preferable that a material for forming the heat-absorbing support may have a melting point of at least 1,000° C.

The heat-absorbing support may be in the form of a plate, a wafer, a film, or a mesh. The heat-absorbing support may have a thickness of about 10 μm to about 1,000 μm, and the BN layer may have a thickness of about 5 μm to about 500 μm. The thickness of the heat-absorbing support may be in the range of about 30 μm to about 800 μm, for example, about 50 μm to about 500 μm, for example, about 100 μm to about 500 μm. The thickness of the BN layer may be in the range of about 5 μm to about 500 μm, for example, about 10 μm to about 300 μm, for example, about 30 μm to about 200 μm, for example, about 50 μm to about 150 μm.

The BN heat dissipation layer may include hexagonal (h)-BN and/or cubic (c)-BN.

In the heat radiation sheet, the heat-absorbing layer and the BN heat dissipation layer are configured to each independently have high thermal conductivity but to have different thermal conductivities. In this regard, the heat-absorbing support formed using a metal plate, film or foil, and the like having high heat absorption capacity serves to preferentially and rapidly absorb heat, and the BN heat dissipation layer formed on at least one of the upper and lower surfaces of the heat-absorbing support also has high thermal conductivity and thus may rapidly radiate, to the outside, the absorbed heat both in a horizontal direction and in a vertical direction.

In addition, the heat radiation sheet manufactured using the method described above may be applied to various electronic devices, optical devices, energy-related devices, and the like due to the fact that the BN heat dissipation layer is formed on at least one of the upper and lower surfaces of a generally flexible metal plate, film or foil and the like. For example, when the heat radiation sheet is used to manufacture a light emitting device, the heat-absorbing support may be a support formed of aluminum oxide, for example, a sapphire support. General light emitting devices are manufactured by growing gallium nitride on a sapphire support. In this regard, the sapphire support has low heat radiation efficiency and thus luminous characteristics easily deteriorate by heat generated when a light emitting device operates at high power output levels. When the heat radiation sheet is used as a substrate in the manufacture of a light emitting device, taking into consideration the fact that GaN is not grown well on the BN layer, the BN heat dissipation layer is partially removed by patterning to expose the sapphire support positioned therebelow and GaN is grown on the sapphire support. The light emitting device manufactured according to the process described above uses a substrate in which the BN heat dissipation layer with high thermal conductivity is formed on an inorganic support such as a sapphire support and thus has high heat radiation efficiency. Thus, even when the light emitting device operates at high power output levels, it may satisfactorily radiate heat generated to the outside and thus the luminous characteristics of the light emitting device may be enhanced.

A heat radiation sheet according to an exemplary embodiment includes a heat-absorbing metal support; and a heat dissipation layer including a BN layer and formed on at least one surface of the heat-absorbing metal support. A heat radiation sheet according to an exemplary embodiment includes a heat-absorbing tungsten or molybdenum foil support; and a heat dissipation layer including a BN layer and formed on at least one surface of the tungsten or molybdenum foil support.

Hereinafter, a method of manufacturing the heat radiation sheet including the BN heat dissipation layer will be described in detail.

First, the heat-absorbing support described above is prepared and, thereafter, a carbon-containing organic or inorganic precursor layer is formed on at least one surface of the heat-absorbing support. A carbon-containing organic precursor is not particularly limited so long as it is a carbon-containing organic polymer, and a carbon-containing inorganic precursor may be a carbon-containing inorganic material selected from graphite, a carbon nanotube, a carbon fiber, graphene, graphene oxide, activated carbon, and carbon black. Examples of the carbon-containing organic polymer include polymethyl methacrylate, polyaniline, polyimide, and the like which are commercially available. The carbon-containing organic or inorganic precursor layer may be formed by spin coating, dip coating, spray coating, roll coating, gravure coating, comma coating, die coating, or vapor deposition. The vapor deposition process may be performed using a deposition method appropriately selected from chemical vapor deposition (CVD) such as metal-organic CVD (MOCVD), plasma-enhanced CVD (PECVD), or microwave plasma-assisted CVD (MPCVD) and physical vapor deposition such as e-beam evaporation, thermal deposition, or sputtering, taking into consideration properties of materials used. However, the vapor deposition method is not limited to the above examples.

Subsequently, the heat-absorbing support with the carbon-containing organic or inorganic precursor layer formed on at least one surface thereof is heat-treated in a nitrogen-containing gas atmosphere and in the presence of a boron-containing compound so that the carbon-containing organic or inorganic precursor layer is converted into a BN layer.

The heat treatment method is not particularly limited so long as it enables the carbon-containing organic or inorganic precursor layer to be converted into a BN layer and, for example, the heat treatment process may be performed at a temperature ranging from about 1,000° C. to about 2,000° C. and a pressure of about 1×10¹ Pa to about 1.013×10⁵ Pa at a nitrogen-containing gas flow rate of about 0.5 L/min to about 10 L/min for about 1 hr to 10 hrs. For example, the heat-absorbing support with the carbon-containing organic or inorganic precursor layer formed thereon is put in a graphite crucible positioned in a horizontal or vertical electric furnace and heat-treated under the conditions described above so that the carbon-containing organic or inorganic precursor layer is converted into a graphite-like structure, and the graphite-like structure is grown into a BN layer with good crystal properties by being substituted with a nitrogen atom derived from a nitrogen-containing gas and a boron atom derived from a boron-containing compound such as boron oxide (B₂O₃).

As such, the manufacture of the heat radiation sheet including the heat dissipation layer including the BN layer and formed on at least one surface of the heat-absorbing support is completed.

As described above, in the heat radiation sheet, a carbon-containing organic precursor layer or a carbon-containing inorganic precursor layer is formed on the heat-absorbing support by using a coating process, such as spin coating, spray coating or dip coating, or by using a vapor deposition process, respectively, which are commonly used in a general semiconductor manufacturing process and the carbon-containing organic or inorganic precursor layer is heat-treated at a high temperature in a horizontal or vertical electric furnace under certain conditions, whereby the layer may be easily converted into a BN heat dissipation layer with high quality. Therefore, according to exemplary embodiments of the present disclosure, a heat radiation sheet with high efficiency may be easily mass-produced using a simple manufacturing process.

In addition, according to the method of manufacturing the heat radiation sheet as described above, the BN layer is formed by heat-treating the carbon-containing organic or inorganic precursor layer strongly adhered to the heat-absorbing support and thus an adhesive strength between the two layers is strong. In addition, the BN layer has high durability due to high crystal quality and high strength of BN constituting the BN layer.

Hereinafter, a substrate for a light emitting device that includes the BN heat dissipation layer, a light emitting device including the substrate, and methods of manufacturing the substrate and the light emitting device will be described in detail with reference to the accompanying drawings.

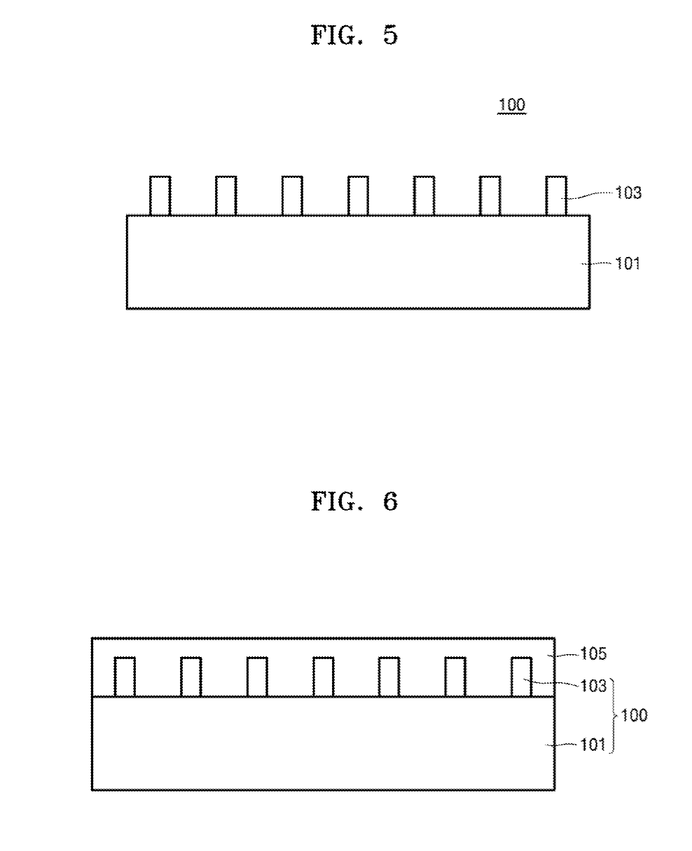

FIG. 5 is a side cross-sectional view of a substrate 100 for a light emitting device according to an exemplary embodiment. Referring to FIG. 5, the substrate 100 includes an inorganic support 101 and a BN pattern layer 103 formed on the inorganic support 101. An area ratio of the BN pattern layer 103 to the inorganic support 101 may be in the range of about 20% to about 80%, for example, about 30% to about 70%, for example, about 40% to about 70%, for example, about 50% to about 70%, for example, about 60% to about 70%. A semiconductor layer such as gallium nitride (GaN) and the like is not grown well on a BN heat dissipation pattern layer. Thus, the BN heat dissipation pattern layer is patterned so as to expose a partial area of the inorganic support such as a sapphire support by adjusting the area ratio to be within the ranges described above, whereby excellent heat radiation effects and appropriate light emitting device manufacturing efficiency may be balanced.

The type of the BN pattern layer 103 is not particularly limited and, for example, as illustrated in FIG. 5, the BN pattern layer 103 may have a stripe shape consisting of a plurality of lines.

In some embodiments, the inorganic support 101 may be an insulating support, a conductive support, or a semiconductor support. For example, the inorganic support 101 may include a material selected from sapphire (Al₂O₃), silicon (Si), silicon carbide (SiC), gallium nitride (GaN), germanium (Ge), gallium arsenide (GaAs), zinc oxide (ZnO), silicon germanium (SiGe), gallium oxide (Ga₂O₃), lithium gallium oxide (LiGaO₂), lithium aluminum oxide (LiAlO₂), and magnesium aluminum oxide (MgAl₂O₄). For the epitaxial growth of a GaN material, the use of a GaN support, i.e., a homo-support, which is composed of the same material, is desirable, but such a GaN support has high manufacturing costs due to difficulties in manufacturing processes. As a hetero-support, i.e. a support composed of other material than GaN, a SiC support, a Si support, or the like is mainly used, and a sapphire or Si support is more widely used than a SiC support, which is expensive.

In an exemplary embodiment, the substrate 100 includes a sapphire support 101 and a BN heat dissipation pattern layer 103 formed on the sapphire support 101. In another exemplary embodiment, the substrate 100 includes the sapphire support 101, the BN heat dissipation pattern layer 103 formed on the sapphire support 101, and an undoped GaN layer grown on the sapphire support 101 and the BN heat dissipation pattern layer 103 as a buffer layer 105 (see FIG. 6), which will be described below, and an area ratio of the BN heat dissipation pattern layer to the sapphire support may be in the range of about 60% to about 70%.

A general light emitting device is manufactured by growing GaN on a sapphire support. In this regard, the sapphire support has very low thermal conductivity and thus luminous characteristics of the light emitting device easily deteriorate due to heat generated when the light emitting device operates at high power output levels. A light emitting device including the substrate according to an exemplary embodiment uses the substrate in which the BN heat dissipation pattern layer is formed on the inorganic support such as a sapphire support and thus exhibits high heat radiation efficiency. Thus, even when the light emitting device operates at high power output levels, it may satisfactorily radiate heat generated to the outside, which results in enhanced luminous characteristics of the light emitting device.

The BN heat dissipation pattern layer may include h-BN and/or c-BN. In the light emitting device according to an exemplary embodiment, the BN heat dissipation pattern layer is characterized as a path for heat radiation from the light emitting device.

Hereinafter, a method of manufacturing the substrate for a light emitting device including the BN heat dissipation pattern layer will be described in detail.

First, the inorganic support described above is prepared and, thereafter, a carbon-containing organic or inorganic precursor pattern layer is formed on the inorganic support. For this, generally, a carbon-containing organic or inorganic precursor layer that covers the entire surface of the inorganic support is formed. A carbon-containing organic precursor is not particularly limited so long as it is a carbon-containing organic polymer, and a carbon-containing inorganic precursor may be a carbon-containing inorganic material selected from graphite, graphene, graphene oxide, activated carbon, a carbon nanotube, and carbon black. Examples of the carbon-containing organic polymer include polymethyl methacrylate, polyaniline, polyimide, and the like which are commercially available. The carbon-containing organic or inorganic precursor layer may be formed by spin coating, dip coating, spray coating, or vapor deposition. The vapor deposition process may be performed using a vapor deposition method appropriately selected from chemical vapor deposition and physical vapor deposition such as e-beam evaporation, thermal deposition, or sputtering, taking into consideration properties of materials used.

Thereafter, the carbon-containing organic or inorganic precursor layer that covers the entire surface of the inorganic support is patterned by a photolithographic process using a photoresist generally used in a semiconductor manufacturing process so as to partially expose the surface of the inorganic support. In this regard, a photoresist pattern is formed such that an area ratio of the carbon-containing organic or inorganic precursor pattern layer to the inorganic support is in the range of about 20% to about 80%. The shape of the photoresist pattern is not particularly limited and may be, for example, a stripe shape consisting of a plurality of lines. When the carbon-containing organic or inorganic precursor pattern layer is patterned using the photoresist pattern as an etching mask pattern, the layer may be etched using an etching method appropriately selected from wet etching and dry etching used in a general semiconductor device manufacturing process.

Subsequently, the inorganic support including the carbon-containing organic or inorganic precursor pattern layer is heat-treated under a nitrogen-containing gas atmosphere and in the presence of a boron-containing compound so that the carbon-containing organic or inorganic precursor pattern layer is converted into a BN pattern layer.

The heat treatment conditions are not particularly limited so long as they enable the carbon-containing organic or inorganic precursor pattern layer to be converted into the BN pattern layer. For example, the heat treatment process may be performed at a temperature ranging from about 1,000° C. to about 2,000° C. and a pressure of about 1×10¹ Pa to about 1.013×10⁵ Pa at a nitrogen-containing gas flow rate of about 0.5 L/min to about 10 L/min for about 1 hr to 10 hrs. For example, the inorganic support including the carbon-containing organic or inorganic precursor pattern layer is put in a graphite crucible positioned in a horizontal or vertical electric furnace and heat-treated under the conditions described above so that the carbon-containing organic or inorganic precursor pattern layer is converted into a graphite-like structure, and the graphite-like structure is grown into a BN pattern layer with good crystal properties by being substituted with a nitrogen atom derived from the nitrogen-containing gas and a boron atom derived from the boron-containing compound such as boron oxide (B₂O₃). Examples of the nitrogen-containing gas include nitrogen gas, ammonia (NH₃) gas, and urea steam.

Hereinafter, a light emitting device including the substrate for light emitting devices that includes the BN heat dissipation pattern layer and a method of manufacturing the same will be described in detail.

Light emitting devices according to exemplary embodiments of the present disclosure are light emitting devices having enhanced heat radiation characteristics and a small volume or compact structure by directly growing a light emitting device structure on the substrate including the BN heat dissipation pattern layer with good crystal properties.

FIG. 10 is a side cross-sectional view of a light emitting device 200 manufactured using the substrate 100 of FIG. 5, according to an exemplary embodiment. Referring to FIG. 10, the light emitting device 200 includes the substrate 100 including the inorganic support 101 and the BN pattern layer 103 formed on the inorganic support 101 and an optional buffer layer 105 to cover and planarize the BN pattern layer 103, a first conductive type semiconductor layer 107, an active layer 109, and a second conductive type semiconductor layer 111 that are sequentially stacked on the substrate 100. In this regard, the first conductive type semiconductor layer 107, the active layer 109, and the second conductive type semiconductor layer 111 may be collectively referred to as a light emitting laminate body 120.

The inorganic support 101 may be disposed below the first conductive type semiconductor layer 107 so as to support the first conductive type semiconductor layer 107. The inorganic support 101 and, in particular, the BN pattern layer 103 with high thermal conductivity may receive heat from the first conductive type semiconductor layer 107 and radiate the received heat to the outside. The inorganic support 101 may have light transmissive properties. The inorganic support 101 may have light transmissive properties when prepared using a light transmissive material or formed to equal to or less than a certain thickness. To increase light extraction efficiency, the inorganic support 101 may have a smaller index of refraction than that of the first conductive type semiconductor layer 107.

In some embodiments, the inorganic support 101 may be an insulating support, a conductive support, or a semiconductor support. For example, the inorganic support 101 may include a material selected from sapphire (Al₂O₃), Si, SiC, GaN, Ge, GaAs, ZnO, SiGe, Ga₂O₃, LiGaO₂, LiAlO₂, and MgAl₂O₄. For the epitaxial growth of a GaN material, the use of a GaN support, which is a homo-support, is desirable, but such a GaN support has high manufacturing costs due to difficulties in manufacturing processes. As a hetero-support, a SiC support, a Si support, or the like is mainly used, and a sapphire or Si support is more widely used than a SiC support, which is expensive. When such a hetero-support is used, defects, e.g., dislocation and the like, increase due to a difference in lattice constants between a support material and a thin film material being grown thereon. In addition, when there is a change in temperature, bending may occur due to a difference in thermal expansion coefficient between the support material and the thin film material, which may result in cracks in the thin film. Selectively, the buffer layer 105 may be used to decrease the difference in lattice constants between a material for forming the inorganic support 101 and a GaN-based material for forming the first conductive type semiconductor layer 107 to reduce the aforementioned problems.

In some embodiments, the inorganic support 101 may be completely or partially removed or patterned in a chip manufacturing process in order to enhance optical or electrical characteristics of a LED chip before or after the growth of a LED structure. For example, a sapphire support may be separated by irradiating an interface between the support and a semiconductor layer with laser beams via the support, and a Si or SiC support may be removed using a method such as polishing/etching or the like. The sapphire support is a crystal body having hexa-rhombo (Hexa-Rhombo R3c) symmetry, has a lattice constant of 13.001 Å in c-axis orientation and a lattice constant of 4.758 Å in a-axis orientation, and has a C(0001) plane, an A(1120) plane, an R(1102) plane, and the like. In this case, the C plane allows a nitride thin film to be grown thereupon relatively easily and is stable at a high temperature, and thus the sapphire support is mainly used as a support for nitride growth.

Another example of the inorganic support is a Si support and such a Si support is more suitable for use in large diameter application and relatively inexpensive and thus may have improved mass productivity. A Si support having a (111) plane as a support plane has a lattice constant difference of about 17% from that of GaN and thus there is a need to develop a technique for suppressing occurrence of crystal defects due to the difference in lattice constants. In addition, a difference in thermal expansion coefficient between silicon and GaN is about 56% and thus there is a need to develop a technique for suppressing wafer bending occurring due to the difference in thermal expansion coefficient. Due to such wafer bending, cracks may occur in a GaN thin film, and problems, e.g., an increased wavelength distribution of the emitted light in the same wafer, may occur due to difficulties in the control of manufacturing processes.

The Si support absorbs light generated from a GaN-based semiconductor and thus external quantum efficiency of the light emitting device decreases. Thus, in some embodiments, the Si support is removed and, instead, a support formed of Si, Ge, SiAl, a ceramic, a metal, or the like and further including a reflective layer may be used.

When a GaN thin film is grown on a hetero-support such as a Si support, dislocation density increases due to inconsistency between lattice constants of the support material and the thin film material, and cracks and bending may occur due to a difference in thermal expansion coefficient therebetween. To prevent dislocation and cracks of the light emitting laminate body 120, the buffer layer 105 may be disposed between the inorganic support 101 and the light emitting laminate body 120. The buffer layer 105 adjusts a degree to which the inorganic support 101 bends during the growth of the active layer 109 and thus also serves to decrease the wavelength distribution of the wafer.

The buffer layer 102 may include AlₓIn_{y}Ga_{(1-x-y)}N where 0≦x≦1, 0≦y≦1, and 0≦x+y≦1, in particular, GaN, AlN, AlGaN, InGaN, or InGaNAlN. The buffer layer 102 may be, in particular, an undoped GaN layer that is not doped with impurities.

As the Si support has a big difference in thermal expansion coefficient from that of GaN, in a process of growing a GaN-based thin film on the Si support, when the GaN-based thin film is grown at a high temperature and then cooled down to room temperature, tensile stress is applied on the GaN-based thin film due to a difference in thermal expansion coefficient between the substrate and the thin film and, as a result, cracks easily occur in the thin film. To prevent the occurrence of cracks, tensile stress is compensated using a method of growing a thin film such that compressive stress is applied on the thin film.

Since Si has a difference in lattice constants from those of GaN and thus has a large possibility of the occurrence of defects. When a Si support is used, both the control of defects and stress control for suppressing bending are required and thus a buffer layer having a composite structure may be used.

The first conductive type semiconductor layer 107 and the second conductive type semiconductor layer 111 may be an n-type semiconductor layer doped with an n-type impurity and a p-type semiconductor layer doped with a p-type impurity, respectively. However, the first and second conductive type semiconductor layers 107 and 111 are not limited to the above examples and may be, for example, a p-type semiconductor layer and an n-type semiconductor layer, respectively. For example, the first and second conductive type semiconductor layers 107 and 111 may be formed of a Group III nitride semiconductor, e.g., a material having the formula AlₓIn_{y}Ga_{(1-x-y)}N where 0≦x≦1, 0≦y≦1, and 0≦x+y≦1. The n-type semiconductor layer may be an n-type GaN layer, and the p-type semiconductor layer may be a p-type GaN layer. The n-type and p-type semiconductor layers are not limited to the above examples and may include, for example, an AlGaInP-based semiconductor or an AlGaAs-based semiconductor.

Each of the first and second conductive type semiconductor layers 107 and 111 may have a single layer structure and, in some embodiments, may have a multilayer structure including multiple layers each with different compositions and/or thicknesses. For example, each of the first and second conductive type semiconductor layers 107 and 111 may include a carrier injection layer for enhancing the injection efficiency of electrons and holes.

The active layer 109 is formed on the first conductive type semiconductor layer 107. The active layer 109 selectively includes a single quantum well structure, a multiple quantum well (MQW) structure in which quantum well layers and quantum barrier layers are alternately stacked, a quantum wire structure, or a quantum dot structure and has a cycle of a well layer and a barrier layer. The well layer may have the formula InₓAl_{y}Ga_{1-x-y}N where 0≦x≦1, 0≦y≦1, and 0≦x+y≦1, and the barrier layer may have the formula InₓAl_{y}Ga_{1-x-y}N where 0≦x≦1, 0≦y≦1, and 0≦x+y≦1. For the MQW structure, e.g., a nitride semiconductor, a GaN/InGaN structure may be used. The cycle of a well layer/a barrier layer may be at least one cycle of a well layer/a barrier layer using a stacked structure of InGaN/GaN, GaN/AlGaN, InGaN/AlGaN, InGaN/InGaN, or InAlGaN/InAlGaN. The barrier layer may be formed of a semiconductor material having a higher bandgap than that of the well layer.

The first conductive type semiconductor layer 107, the active layer 109, and the second conductive type semiconductor layer 111 may be prepared using an MOCVD apparatus. A reaction vessel, in which the inorganic support 101 with the BN pattern layer 103 formed thereon is positioned, is provided with, as a reactive gas, an organic metal compound gas (e.g., trimethyl gallium (TMG), trimethyl aluminum (TMA), or the like) and a nitrogen-containing gas (ammonia (NH₃) or the like) and the temperature of the inorganic support 101 is maintained at a high temperature, e.g., from about 900° C. to about 1100° C. so that a GaN-based compound semiconductor is grown on the inorganic support. At the same time, if desired, the reaction vessel is further provided with an impurity gas so that the GaN-based compound semiconductor is stacked to be of undoped type, n-type, or p-type. Si is well known as an n-type impurity, and examples of a p-type impurity include Zn, Cd, Be, Mg, Ca, Ba, and the like and Mg and Zn may be mainly used.

The light emitting device 200 may further include an ohmic contact layer (not shown) on an upper portion of the second conductive type semiconductor layer 111. The ohmic contact layer may have a relatively increased concentration of impurities and thus a decreased ohmic contact resistance, which results in a decrease in operating voltage of the light emitting device and enhanced device characteristics thereof. The ohmic contact layer may consist of GaN, InGaN, ZnO, or a graphene layer.

The light emitting device 200 may further include first and second electrodes 113 and 115 for power supply. The first and second electrodes 113 and 115 may include a material such as silver (Ag), nickel (Ni), aluminum (Al), rhodium (Rh), palladium (Pd), iridium (Ir), ruthenium (Ru), magnesium (Mg), zinc (Zn), platinum (Pt), gold (Au), or the like and may have a structure including at least two layers formed of Ni/Ag, Zn/Ag, Ni/Al, Zn/Al, Pd/Ag, Pd/Al, Ir/Ag, Ir/Au, Pt/Ag, Pt/Al, Ni/Ag/Pt, or the like. When an ohmic contact layer (not shown) is formed on the second conductive type semiconductor layer 111, the second electrode 115 is formed on a partial area of the ohmic contact layer.

The light emitting device 200 illustrated in FIG. 10, e.g., an LED chip, according to one exemplary embodiment, has a structure in which the first and second electrodes 113 and 115 face the same direction as a direction in which a light extraction surface faces. In other exemplary embodiments, the light emitting device 200 may have various structures such as a flip-chip structure in which first and second electrodes are positioned opposite to a light extraction surface, a vertical structure in which first and second electrodes are formed at opposing surfaces, a vertical/horizontal structure as a structure for increasing current distribution efficiency and heat radiation efficiency in which several vias are formed and electrode structures are employed therein, and the like.

A light emitting package according to an exemplary embodiment includes a printed circuit board, the light emitting device described above mounted on the printed circuit board, and an encapsulation member to encapsulate the light emitting device.

Hereinafter, the light emitting device including the substrate for a light emitting device that includes the BN heat dissipation pattern layer, as described above, and a method of manufacturing the same will be described in detail.

FIGS. 6 to 10 are side cross-sectional views sequentially illustrating a process of manufacturing a light emitting device using the substrate 100 of FIG. 1.

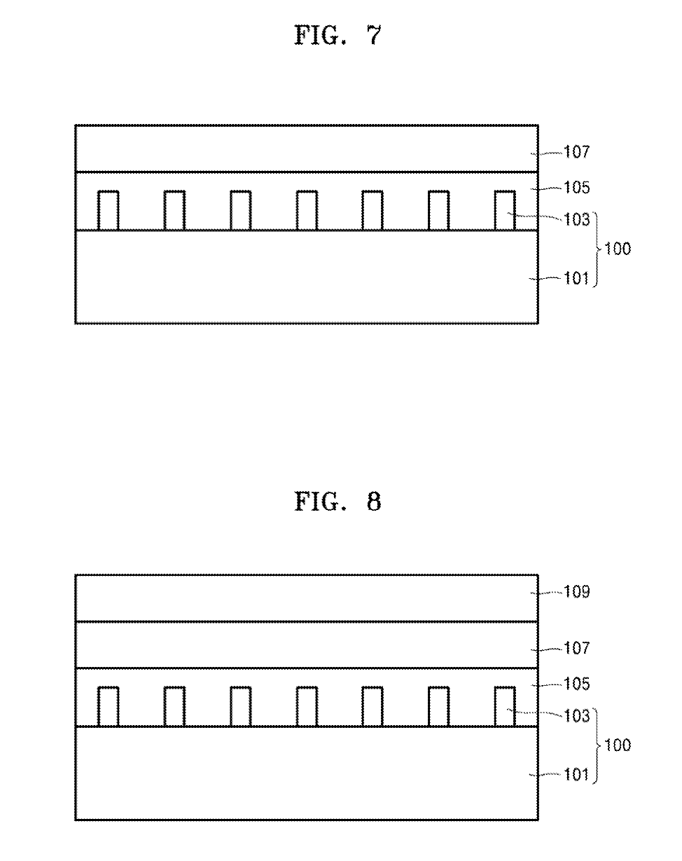

Referring to FIGS. 6 and 7, the substrate 100 of FIG. 5 including the inorganic support 101 and the BN pattern layer 103 formed on the inorganic support 101 is prepared. First, before forming the first conductive type semiconductor layer 107 on the inorganic support 101, the buffer layer 105 is formed so as to cover and planarize the BN pattern layer 103. Subsequently, the first conductive type semiconductor layer 107 may be formed on the buffer layer 105. Detailed configurations of the substrate 100, the buffer layer 105, and the first conductive type semiconductor layer 107 have already been provided with reference to FIG. 6 and thus a detailed description thereof will be omitted herein.

A gallium precursor, a nitrogen precursor, an n-type dopant precursor, and a carrier gas may be supplied into a reaction chamber in which the substrate 100 with an n-GaN layer as the first conductive type semiconductor layer 107 formed thereon is accommodated. The first conductive type semiconductor layer 107 may be formed by using, for example, MOCVD. However, the deposition method is not limited to the above example.

The gallium precursor may be, for example, trimethylgallium (TMG), triethylgallium (TEG), diethylgallium chloride, or the like. The nitrogen precursor may be, for example, ammonia, nitrogen, or plasma-excited species of ammonia and/or nitrogen. In some embodiments, an n-type dopant may be Si and a precursor thereof may be a silane compound.

Referring to FIG. 8, the active layer 109 is formed on the first conductive type semiconductor layer 107. In a case in which the active layer 109 has an MQW structure including InGaN well layers and GaN barrier layers, a gallium source gas and a nitrogen source gas may be supplied into the reaction chamber to form the barrier layers and an indium source gas may be further supplied into the reaction chamber to form the well layers. The source gases for forming the barrier and well layers may be simultaneously supplied into the reaction chamber or may be sequentially supplied into the reaction chamber in an alternate order.

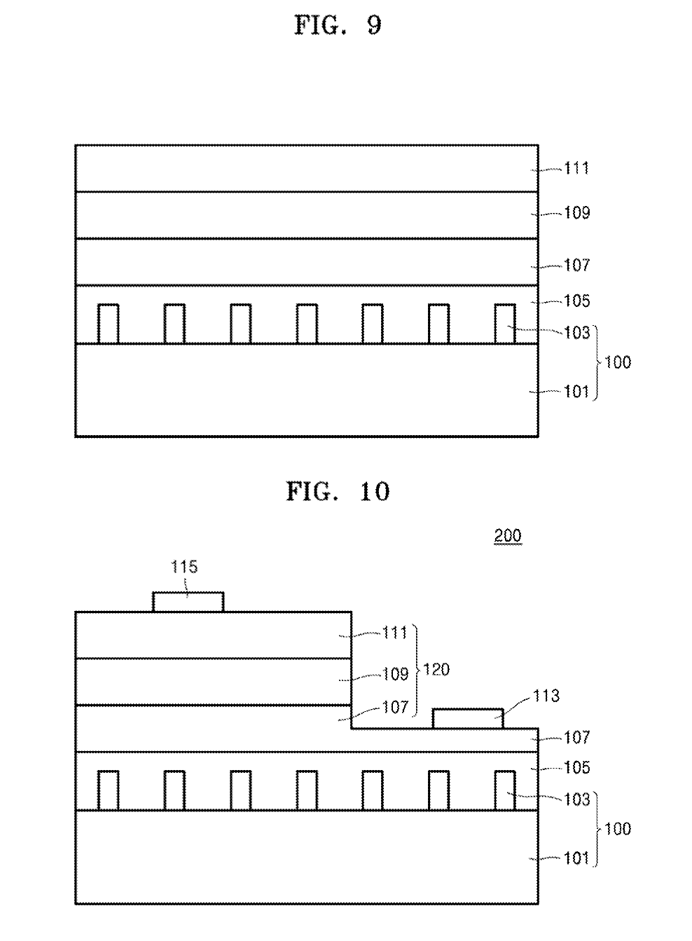

Referring to FIG. 9, the second conductive type semiconductor layer 111 may be formed on the active layer 109. When the second conductive type semiconductor layer 111 is a p-GaN layer, a gallium precursor and a nitrogen precursor may be supplied into the reaction chamber to cause a reaction. The p-type dopant precursor used may be, for example, bis(cyclopentadienyl), usually denoted as Cp₂Mg, but is not limited thereto.

Referring to FIG. 10, an ohmic contact layer (not shown) is selectively formed on the second conductive type semiconductor layer 111 and, thereafter, a mesa is formed so as to expose the first conductive type semiconductor layer 107. Afterwards, the first electrode 113 and the second electrode 115 may be formed on the first conductive type semiconductor layer 107 and the second conductive type semiconductor layer 111, respectively.

Hereinafter, a back sheet for a photovoltaic module that includes the BN layer, a method of manufacturing the same, and a photovoltaic module including the back sheet will be described in detail with reference to the accompanying drawings.

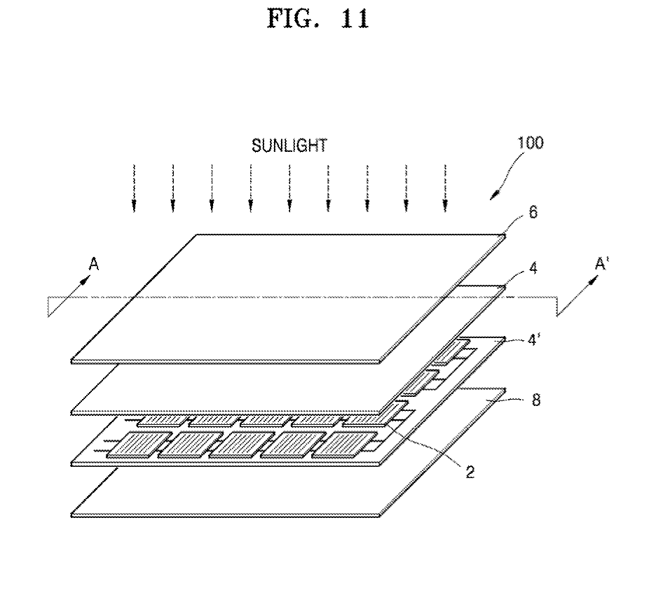

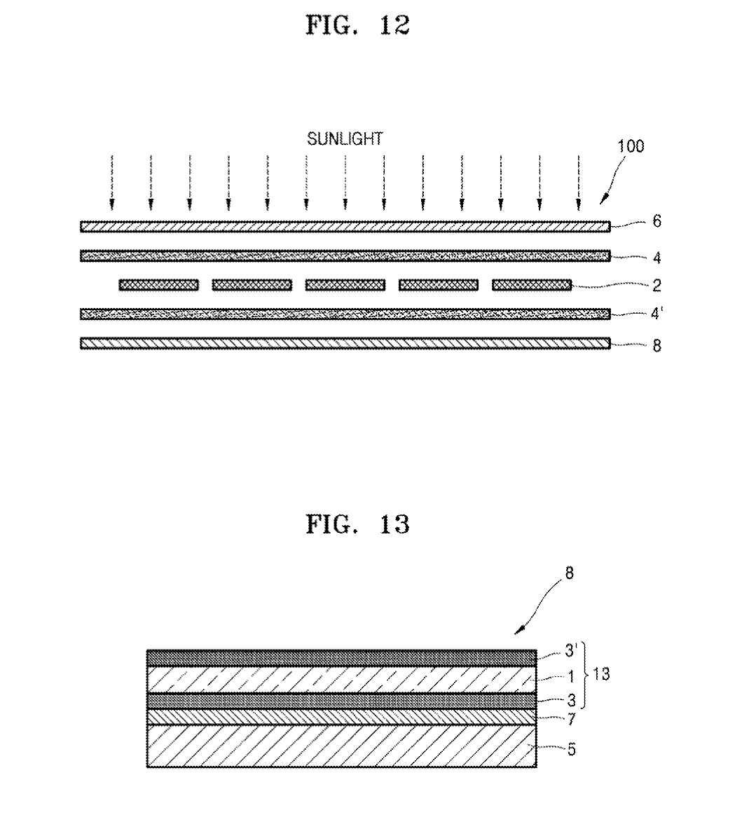

FIG. 11 is a perspective view of a photovoltaic module 100 according to an exemplary embodiment. FIG. 12 is a cross-sectional view taken along a line A-A′ of FIG. 11.

Referring to FIGS. 11 and 12, the photovoltaic module 100 includes photovoltaic cells 2, upper and lower encapsulation layers 4 and 4′ respectively attached to upper and lower surfaces of the photovoltaic cells 2, an upper surface layer 6 attached to the upper encapsulation layer 4, and a back sheet 8 attached to the lower encapsulation layer 4′.

Each of the upper and lower encapsulation layers 4 and 4′ includes an olefin-based copolymer film, for example, an EVA layer. The upper surface layer 6 includes a glass layer and is a side on which sunlight is incident.

The back sheet 8 protects the photovoltaic cells 2 and exhibits heat radiation performance and thus rapidly and effectively radiates heat generated from the photovoltaic cells 2 and heat applied from external environments and external devices, whereby the power generation efficiency of the photovoltaic module is maximized.

FIG. 13 is a cross-sectional view particularly illustrating a stacked structure of the back sheet 8 for the photovoltaic module illustrated in FIGS. 11 and 12.

Referring to FIG. 13, the back sheet 8 includes: a heat dissipation layer 13 including a metal layer 1, a first BN layer 3 formed on a lower surface of the metal layer 1, and a second BN layer 3′ formed on an upper surface of the metal layer 1; the protective layer 5 formed on one surface of the heat dissipation layer 13; and an adhesive layer 7 that adheres the protective layer 5 to the heat dissipation layer 13.

The metal layer 1 may include a material selected from the group consisting of tungsten, titanium, iron, copper, nickel, silver, zinc, molybdenum, and alloys including one or more of these metals. The metal layer 1 may have a thickness of about 10 μm to about 1,000 μm, and the first and second BN layers 3 and 3′ may have a thickness of about 5 μm to about 500 μm. The thickness of the metal layer 1 may be in the range of about 30 μm to about 800 μm, for example, about 50 μm to about 500 μm, for example, about 100 μm to about 500 μm. The thickness of each of the first and second BN layers 3 and 3′ may be in the range of about 5 μm to about 500 μm, for example, about 10 μm to about 300 μm, for example, about 30 μm to about 200 μm, for example, about 50 μm to about 150 μm.

The first and second BN layers 3 and 3′ may include h-BN and/or c-BN.

The protective layer 5 may include a film selected from the group consisting of a fluorinated resin film, a polyester film, a polyolefin film, and a polyolefin-based copolymer film. For example, the protective layer 5 may include a film selected from the group consisting of a polyvinylidene fluoride (PVDF) film, a polyethylene terephthalate (PET) film, a polyethylene (PE) film, a polypropylene (PP) film, and an EVA film.

The adhesive layer 7 strongly adheres the protective layer 5 to the heat dissipation layer 13 and thus may satisfactorily protect the heat dissipation layer 13.

In the back sheet 8 for a photovoltaic module, instead of forming adhesive layers on upper and lower surfaces of the metal layer 1 with high thermal conductivity, the first and second BN layers 3 and 3′, exhibiting electrically insulating properties and excellent heat radiation performance both in a horizontal direction and in a vertical direction, is closely attached to the metal layer 1. The metal layer 1 and the first and second BN layers 3 and 3′ are formed such that the metal layer 1 and the BN layers 3 and 3′ layers each independently have high thermal conductivity but have different thermal conductivities. In this regard, the metal layer 1 with high heat absorbing capacity first absorbs heat rapidly and then the first and second BN layers 3 and 3′ may rapidly radiate the absorbed heat both in a horizontal direction and in a vertical direction due to their high thermal conductivity.

In the manufacture of the back sheet 8, carbon-containing organic or inorganic precursor layers strongly adhered to the metal layer 1 are heat-treated, thereby forming the first and second BN layers 3 and 3′ and thus an adhesive strength therebetween is strong without the formation of adhesive layers and BN constituting the first and second BN layers 3 and 3′ has high crystal quality and high strength and thus imparts high durability.

Thus, the back sheet 8 generally exhibits electrically insulating characteristics, excellent heat radiation performance both in a horizontal direction and in a vertical direction, as well as high durability. Therefore, the back sheet 8 has excellent heat radiation characteristics and thus may effectively prevent, for a long period of time, performance degradation of a photovoltaic module due to heating of photovoltaic cells by direct sunlight and waste heat generated during photovoltaic conversion.

In the back sheet according to one exemplary embodiment, the BN layer is formed such that a carbon-containing organic or inorganic precursor layer is heat-treated to be converted into the BN layer. Thus, taking into consideration the fact that the high-temperature heat-treatment process is generally performed at a temperature between about 1000° C. and about 2000° C., it may be preferable that a material for forming the heat-absorbing support may have a melting point of at least 1000° C.

In an exemplary embodiment, the back sheet for a photovoltaic module includes: the heat dissipation layer 13 including tungsten or molybdenum foil 1, the first BN layer 3 formed on a lower surface of the tungsten or molybdenum foil 1, and a second BN layer 3′ formed on an upper surface of the tungsten or molybdenum foil 1; the protective layer 5 formed on one surface of the heat dissipation layer 13; and the adhesive layer 7 that adheres the protective layer 5 to the heat dissipation layer 13.

Hereinafter, a method of manufacturing the back sheet for a photovoltaic module, including the BN layer, will be described in detail.

First, the metal layer described above is prepared and then a carbon-containing organic or inorganic precursor layer is formed on at least one surface of the metal layer. A carbon-containing organic precursor is not particularly limited so long as it is a carbon-containing organic polymer, and a carbon-containing inorganic precursor may be a carbon-containing inorganic material selected from graphite, a carbon nanotube, a carbon fiber, graphene, graphene oxide, amorphous carbon, and carbon black. Examples of the carbon-containing organic polymer include polymethyl methacrylate, polyaniline, polyimide, and the like, which are commercially available. The carbon-containing organic or inorganic precursor layer may be formed by spin coating, dip coating, spray coating, roll coating, gravure coating, comma coating, die coating, or vapor deposition. The vapor deposition process may be performed using a vapor deposition method appropriately selected from CVD such as MOCVD, PECVD, or MPCVD and physical vapor deposition such as e-beam evaporation, thermal deposition, or sputtering, taking into consideration properties of materials used. However, the vapor deposition method is not limited to the above examples.

Subsequently, the metal layer with the carbon-containing organic or inorganic precursor layers formed thereon is heat-treated in a nitrogen-containing gas atmosphere and in the presence of a boron-containing compound so that the carbon-containing organic or inorganic precursor layers are converted into BN layers, thereby completing the formation of a heat dissipation layer including a BN layer(s) formed on at least one surface of the metal layer, for example, a heat dissipation layer including the first and second BN layers formed on opposite surfaces of the metal layer.

The heat treatment method is not particularly limited so long as it enables the carbon-containing organic or inorganic precursor layer to be converted into a BN layer and, for example, the heat-treatment process may be performed at a temperature ranging from about 1,000° C. to about 2,000° C. and a pressure of about 1×10¹ Pa to about 1.013×10⁵ Pa at a nitrogen-containing gas flow rate of about 0.5 L/min to about 10 L/min for about 1 hr to 10 hrs. For example, the metal layer with the carbon-containing organic or inorganic precursor layer formed thereon is put in a graphite crucible positioned in a horizontal or vertical electric furnace and heat-treated under the conditions described above so that the carbon-containing organic or inorganic precursor layer is converted into a graphite-like structure, and the graphite-like structure is grown into a BN layer with good crystal properties by being substituted with a nitrogen atom derived from a nitrogen-containing gas and a boron atom derived from a boron-containing compound such as boron oxide (B₂O₃).

As such, the heat dissipation layer, including the metal layer and at least one BN layer(s) formed on at least one surface of the metal layer, for example, including the metal layer and the first and second BN layers formed on both of the opposite surfaces of the metal layer, is formed.

Subsequently, an adhesive layer is formed on one surface of the heat dissipation layer and then a protective layer is aligned on the adhesive layer and compressed, thereby completing the manufacture of the back sheet in which the protective layer is attached to the heat dissipation layer by the adhesive layer therebetween.

As described above, in the back sheet, a carbon-containing organic precursor layer or a carbon-containing inorganic precursor layer is formed on the heat-absorbing support by using a coating process, such as spin coating, spray coating or dip coating and by a vapor deposition process, respectively, which are commonly used in a general semiconductor manufacturing process and the carbon-containing organic or inorganic precursor layer is heat-treated at a high temperature in a horizontal or vertical electric furnace under certain conditions, whereby the layer may be easily converted into a BN layer with high quality. Therefore, according to the exemplary embodiments of the present disclosure, a back sheet with high heat radiation performance and high durability may be easily mass-produced using a simple manufacturing process.

In addition, according to the method of manufacturing the back sheet, a BN layer is formed by heat-treating a carbon-containing organic or inorganic precursor layer strongly adhered to a metal layer and thus an adhesive strength between the two layers is strong without forming an adhesive layer between the two layers and BN constituting the BN layer has high crystal quality and high strength and thus imparts high durability.

According to a conventional method, a film layer is formed on a separate heat radiation sheet formed of a metal and then the resulting structure is attached to a rear portion of a back sheet for a photovoltaic module, which is a complicated and inconvenient process. By contrast, in a back sheet according to an exemplary embodiment of the present disclosure, a heat dissipation layer is directly formed on the back sheet itself, and thus manufacturing processes are simple, and the back sheet has high corrosion resistance.

Hereinafter, one or more embodiments will be described in further detail with reference to the following examples. These examples are for illustrative purposes only and are not intended to limit the scope of the one or more embodiments.

### EXAMPLE 1

A tungsten support having a thickness of about 10 μm to about 100 μm and a square shape with a size of about 1 inch× about 1 inch was washed with acetone, isopropyl alcohol (IPA), and deionized water in this order each for 5 minutes.

A commercially available positive-type photoresist composition (manufacturer: AZ Electronic Materials, Product Name: GXR-601) was dripped onto the washed tungsten support and then spin-coated at a rotating speed of about 4000 rpm for about 60 seconds, followed by drying at a temperature ranging from about 100° C. to about 150° C. for about 1 minute to about 2 minutes, to form a carbon-containing organic precursor layer having a thickness of about 3 μm.

A graphite holder was installed in a horizontal furnace (manufacturer: Nasil Tech Ltd., Product Name: None), the graphite holder was filled with B₂O₃ powder as a boron source, and the tungsten support with the carbon-containing organic precursor layer formed thereon was mounted thereon.

While maintaining the flow rate of a nitrogen gas as a nitrogen atom source to be about 2 L/min, the temperature of the furnace was raised from 30° C. to 1600° C. at a heating rate of 5° C./min, and the furnace was maintained at about 1600° C. for about 5 hours. The pressure of the furnace was maintained at 1.013×10⁵ Pa (atmospheric pressure). As such, the carbon-containing organic precursor layer was converted into a boron nitride (BN) heat dissipation layer.

After forming the BN heat dissipation layer, the furnace was cooled down from 1600° C. to 30° C. at a cooling rate of 5° C./min and, to analyze properties of the BN heat dissipation layer formed after cooling, Raman spectroscopy analysis and scanning electron microscope (SEM) analysis were conducted.

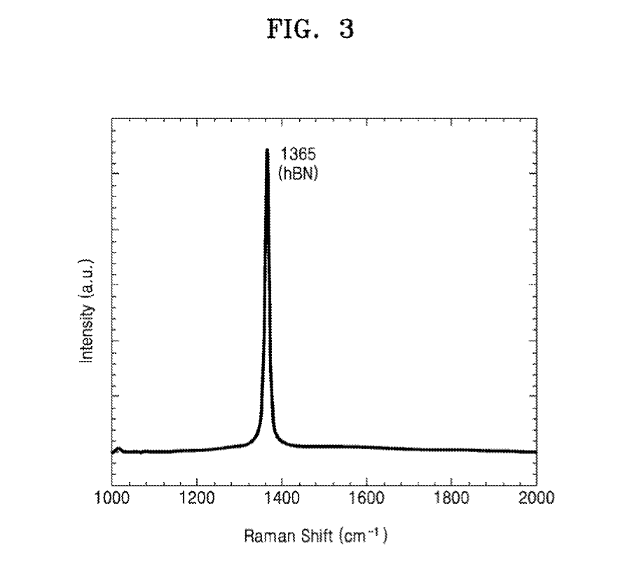

FIG. 3 illustrates Raman spectroscopy analysis results of a surface of the BN heat dissipation layer. Referring to FIG. 3, a characteristic h-BN peak of hexagonal BN is observed at a Raman shift position of about 1365 cm⁻¹.

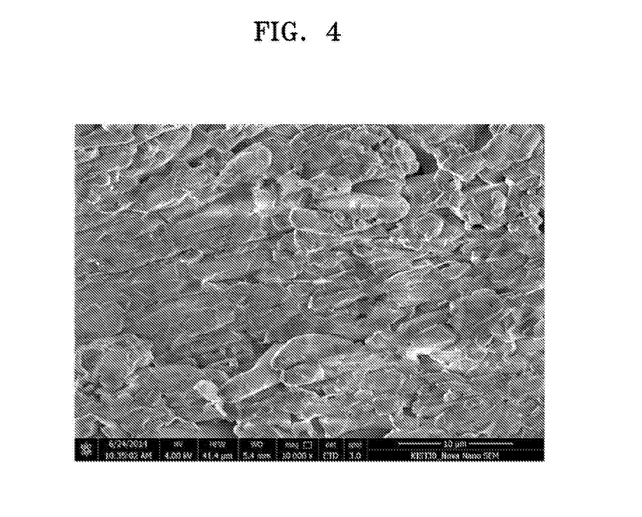

FIG. 4 shows an SEM image of the BN heat dissipation layer. Referring to FIG. 4, it is confirmed that grain boundaries with a size of several micrometers were formed.

### EXAMPLE 2

A molybdenum support having a thickness of about 10 μm to about 100 μm and a square shape with a size of about 1 inch× about 1 inch was washed with acetone, IPA, and deionized water in this order each for 5 minutes.

A polymethyl methacrylate (PMMA) resist (manufacturer: MicroChem, Product Name: NANO™ PMMA) was dripped onto the washed molybdenum substrate and then spin-coated at a rotating speed of about 4000 rpm for about 60 seconds, followed by drying at a temperature of about 170° C. for about 30 minutes, to form a PMMA layer having a thickness of about 100 nm to about 200 nm.

A graphite holder was installed in a horizontal furnace (manufacturer: Nasil Tech Ltd., Product Name: None), the graphite holder was filled with B₂O₃ powder as a boron source, and the molybdenum support with the PMMA layer formed thereon was mounted thereon.

While maintaining the flow rate of a nitrogen gas as a nitrogen source to be about 2 L/min, the temperature of the furnace was raised from 30° C. to 1600° C. at a heating rate of 5° C./min, and the furnace was maintained at about 1600° C. for about 5 hours. The pressure of the furnace was maintained at 1.013×10⁵ Pa (atmospheric pressure). As such, the PMMA layer was converted into a BN heat dissipation layer.

After forming the BN heat dissipation layer, the furnace was cooled down from 1600° C. to 30° C. at a cooling rate of 5° C./min and, to analyze properties of the BN heat dissipation layer formed after cooling, Raman spectroscopy analysis and SEM analysis were conducted.

### EXAMPLE 3

A tungsten support having a thickness of about 10 μm to about 100 μm and a square shape with a size of about 1 inch× about 1 inch was washed with acetone, IPA, and deionized water in this order each for 5 minutes.

A suspension prepared by suspending graphene oxide (GO), which was prepared by using a well-known method, in water was spray-coated on the tungsten support at a temperature ranging from 100° C. to 150° C. and a spray rate of about 1 nm/min to form a GO layer having a thickness of about 1 nm to about 10 nm on the tungsten support.

A graphite holder was installed in a vertical furnace (manufacturer: Nasil Tech Ltd., Product Name: None), the graphite holder was filled with B₂O₃ powder as a boron source, and the tungsten support with the GO layer formed thereon was mounted thereon.

While maintaining the flow rate of a nitrogen gas as a nitrogen atom source to be about 2 L/min, the temperature of the furnace was raised from 30° C. to 1600° C. at a heating rate of 5° C./min, and the furnace was maintained at about 1600° C. for about 5 hours. The pressure of the furnace was maintained at 1.013×10⁵ Pa (atmospheric pressure). As such, the GO layer was converted into a BN heat dissipation layer.

After forming the BN heat dissipation layer, the furnace was cooled down from 1600° C. to 30° C. at a cooling rate of 5° C./min and, to analyze properties of the BN heat dissipation layer formed after cooling, Raman spectroscopy analysis and SEM analysis were conducted.

### EXAMPLE 4

A molybdenum support having a thickness of about 10 μm to about 100 μm and a square shape with a size of about 1 inch× about 1 inch was washed with acetone, IPA, and deionized water in this order each for 5 minutes.

Using graphite (Manufacturer: Taewon Science, Product Name: Graphite Target) as a raw material, plasma-enhanced reactive magnetron sputtering was carried out to form a graphite layer having a thickness of about 10 nm to about 1 μm on the molybdenum support under the following conditions for about 10 minutes to about 60 minutes: operating voltage of 400 V, operating electrical current of 300 mA, Ar flow rate of 50 sccm (standard cubic centimeter per minute), and chamber pressure of 210 mTorr.

A graphite holder was installed in a vertical furnace (manufacturer: Nasil Tech Ltd., Product Name: None), the graphite holder was filled with B₂O₃ powder as a boron source, and the molybdenum support with the graphite layer formed thereon was mounted thereon.

While maintaining the flow rate of a nitrogen gas as a nitrogen atom source to be about 2 L/min, the temperature of the furnace was raised from 30° C. to 1600° C. at a heating rate of 5° C./min, and the furnace was maintained at about 1600° C. for about 5 hours. The pressure of the furnace was maintained at 1.013×10⁵ Pa (atmospheric pressure). As such, the graphite layer was converted into a BN heat dissipation layer.

After forming the BN heat dissipation layer, the furnace was cooled down from 1600° C. to 30° C. at a cooling rate of 5° C./min and, to analyze properties of the BN heat dissipation layer formed after cooling, Raman spectroscopy analysis and SEM analysis were conducted.

### EXAMPLE 5

A sapphire support having a thickness of about 430 μm and a diameter of about 2 inches was washed with acetone, IPA, and deionized water in this order each for 5 minutes.

A commercially available positive-type photoresist composition (manufacturer: AZ Electronic Materials, Product Name: GXR-601) was dripped onto the washed sapphire support and then spin-coated at a rotating speed of about 4000 rpm for about 60 seconds, followed by drying at a temperature ranging from about 100° C. to about 150° C. for about 1 minute to about 2 minutes, to form a carbon-containing organic precursor layer having a thickness of about 3 μm. Subsequently, the carbon-containing organic precursor layer was irradiated, via a mask with a pattern having a plurality of lines, with an energy of about 100 mJ/cm² to about 500 mJ/cm² by adjusting the power output of an ultraviolet light exposure device (manufacturer: Karl Suss, Model Name: MA6) and was subjected to wet developing using a developer (manufactured by AZ Electronic Materials, Product Name: AZ300MIF) to form a carbon-containing organic precursor pattern layer consisting of photoresist patterns having a stripe shape.

A graphite holder was installed in a horizontal furnace (manufacturer: Nasil Tech Ltd.), the graphite holder was filled with B₂O₃ powder as a boron source, and the sapphire support with the carbon-containing organic precursor pattern layer formed thereon was mounted thereon.

While maintaining the flow rate of a nitrogen gas as a nitrogen-containing gas to be about 2 L/min, the temperature of the furnace was raised from 30° C. to 1600° C. at a heating rate of 5° C./min, and the furnace was maintained at about 1600° C. for about 5 hours. The pressure of the furnace was maintained at 1.013×10⁵ Pa (atmospheric pressure). As such, the carbon-containing organic precursor pattern layer was converted into a BN heat dissipation pattern layer.

After forming the BN heat dissipation pattern layer, the furnace was cooled down from 1600° C. to 30° C. at a cooling rate of 5° C./min and, to analyze properties of the BN heat dissipation pattern layer formed after cooling, Raman spectroscopy analysis and SEM analysis were conducted.

As a result of laser Raman spectroscopy analysis of the BN heat dissipation pattern layer, as illustrated in FIG. 3, a characteristic h-BN peak of hexagonal BN may be observed at a Raman shift position of about 1365 cm⁻¹. As a result of SEM analysis of the BN heat dissipation pattern layer, as illustrated in FIG. 4, it is confirmed that grain boundaries with a size of several micrometers were formed.

### EXAMPLE 6

A sapphire support having a thickness of about 430 μm and a diameter of about 2 inches was washed with acetone, IPA, and deionized water in this order each for 5 minutes.

A PMMA resist (manufacturer: MicroChem, Product Name: NANO™ PMMA) was dripped onto the washed sapphire support and then spin-coated at a rotating speed of about 4000 rpm for about 60 seconds, followed by drying at a temperature of about 170° C. for about 30 minutes, to form a PMMA layer having a thickness of about 100 nm to about 200 nm. Subsequently, the PMMA layer was irradiated, via a mask with a pattern having a plurality of lines, with deep ultraviolet (DUV) light with a wavelength of 248 nm and having an energy of about 600 mJ/cm² and then subjected to wet developing using a mixed solvent of methyl isobutyl ketone (MIBK) and IPA at a ratio of 1:1 to form a carbon-containing organic precursor pattern layer consisting of PMMA patterns having a stripe shape.

A graphite holder was installed in a horizontal furnace (manufacturer: Nasil Tech Ltd.), the graphite holder was filled with B₂O₃ powder as a boron source, and the sapphire support with the PMMA pattern layer formed thereon was mounted thereon.

While maintaining the flow rate of a nitrogen gas as a nitrogen-containing gas to be about 2 L/min, the temperature of the furnace was raised from 30° C. to 1600° C. at a heating rate of 5° C./min, and the furnace was maintained at about 1600° C. for about 5 hours. The pressure of the furnace was maintained at 1.013×10⁵ Pa (atmospheric pressure). As such, the PMMA pattern layer was converted into a BN heat dissipation pattern layer.

After forming the BN heat dissipation pattern layer, the furnace was cooled down from 1600° C. to 30° C. at a cooling rate of 5° C./min and, to analyze properties of the BN heat dissipation pattern layer formed after cooling, Raman spectroscopy analysis and SEM analysis were conducted.

### EXAMPLE 7

A sapphire support having a thickness of about 430 μm and a diameter of about 2 inches was washed with acetone, IPA, and deionized water in this order each for 5 minutes.

A commercially available positive-type photoresist composition (manufacturer: AZ Electronic Materials, Product Name: AZ 5214E) was dripped onto the washed sapphire support and then spin-coated at a rotating speed of about 4000 rpm for about 60 seconds, followed by drying at a temperature ranging from about 110° C. to about 120° C. for about 1 minute to about 2 minutes, to form a photoresist layer having a thickness of about 1.5 μm to about 2 μm. Subsequently, the photoresist layer was irradiated, via a mask with a pattern having a plurality of lines, with an energy of about 200 mJ/cm² to about 400 mJ/cm² by adjusting the power output of an ultraviolet light exposure device (manufacturer: Karl Suss, Model Name: MA6) and was subjected to wet developing using a developer (manufactured by AZ Electronic Materials, Product Name: AZ351B) to form photoresist patterns having a stripe shape.

A suspension prepared by suspending graphene oxide (GO), which was prepared by using a well-known method, in water was spray-coated on the entire surface of the photoresist patterns at a temperature of 100° C. to 150° C. and a spray rate of about 1 nm/min to form a GO layer having a thickness of about 1 nm to about 10 nm on the entire surface of the sapphire support.

Subsequently, the photoresist patterns were washed using a photoresist remover (manufacturer: AZ Electronic Materials, Product Name: AZ 100 Remover) to remove both the photoresist patterns and GO formed thereon and, consequently, only a GO pattern layer remained on the sapphire support.

A graphite holder was installed in a vertical furnace (manufacturer: Nasil Tech Ltd.), the graphite holder was filled with B₂O₃ powder as a boron source, and the sapphire support with the GO pattern layer formed thereon was mounted thereon.

While maintaining the flow rate of a nitrogen gas as a nitrogen-containing gas to be about 2 L/min, the temperature of the furnace was raised from 30° C. to 1600° C. at a heating rate of 5° C./min, and the furnace was maintained at about 1600° C. for about 5 hours. The pressure of the furnace was maintained at 1.013×10⁵ Pa (atmospheric pressure). As such, the GO pattern layer was converted into a BN heat dissipation pattern layer.

After forming the BN heat dissipation pattern layer, the furnace was cooled down from 1600° C. to 30° C. at a cooling rate of 5° C./min and, to analyze properties of the BN heat dissipation pattern layer formed after cooling, Raman spectroscopy analysis and SEM analysis were conducted.

### EXAMPLE 8

A sapphire support having a thickness of about 430 μm and a diameter of about 2 inches was washed with acetone, IPA, and deionized water in this order each for 5 minutes.

A commercially available positive-type photoresist composition (manufacturer: AZ Electronic Materials, Product Name: AZ 5214E) was dripped onto the washed sapphire support and then spin-coated at a rotating speed of about 4000 rpm for about 60 seconds, followed by drying at a temperature ranging from about 110° C. to about 120° C. for about 1 minute to about 2 minutes, to form a photoresist layer having a thickness of about 1.5 μm to about 2 μm. Subsequently, the photoresist layer was irradiated, via a mask with a pattern having a plurality of lines, with an energy of about 200 mJ/cm² to about 400 mJ/cm² by adjusting the power output of an ultraviolet light exposure device (manufacturer: Karl Suss, Model Name: MA6) and was subjected to wet developing using a developer (manufactured by AZ Electronic Materials, Product Name: AZ 351B) to form photoresist patterns having a stripe shape.

Using graphite (Manufacturer: Taewon Science, Product Name: Graphite Target) as a raw material, plasma-enhanced reactive magnetron sputtering was carried out to form a graphite layer having a thickness of about 10 nm to about 1 μm on the entire surface of the photoresist patterns under the following conditions for about 10 minutes to about 60 minutes: operating voltage of 400 V, operating electrical current of 300 mA, Ar flow rate of 50 sccm, and chamber pressure of 210 mTorr.

Subsequently, the photoresist patterns were washed using a photoresist remover (manufacturer: AZ Electronic Materials, Product Name: AZ 100 Remover) to remove both the photoresist patterns and graphite formed thereon and, consequently, only a graphite pattern layer remained on the sapphire support.

A graphite holder was installed in a vertical furnace (manufacturer: Nasil Tech Ltd.), the graphite holder was filled with B₂O₃ powder as a boron source, and the sapphire support with the graphite pattern layer formed thereon was mounted thereon.

While maintaining the flow rate of a nitrogen gas as a nitrogen-containing gas to be about 2 L/min, the temperature of the furnace was raised from 30° C. to 1600° C. at a heating rate of 5° C./min, and the furnace was maintained at about 1600° C. for about 5 hours. The pressure of the furnace was maintained at 1.013×10⁵ Pa (atmospheric pressure). As such, the graphite pattern layer was converted into a BN heat dissipation pattern layer.

After forming the BN heat dissipation pattern layer, the furnace was cooled down from 1600° C. to 30° C. at a cooling rate of 5° C./min and, to analyze properties of the BN heat dissipation pattern layer formed after cooling, Raman spectroscopy analysis and SEM analysis were conducted.

### EXAMPLE 9

A tungsten support having a thickness of about 10 μm to about 100 μm and a square shape with a size of about 1 inch× about 1 inch was washed with acetone, IPA, and deionized water in this order each for 5 minutes.

A commercially available positive-type photoresist composition (manufacturer: AZ Electronic Materials, Product Name: GXR-601) was dripped onto a surface of the washed tungsten support and then spin-coated at a rotating speed of about 4000 rpm for about 60 seconds, followed by drying at a temperature ranging from about 100° C. to about 150° C. for about 1 minute to about 2 minutes, to form a carbon-containing organic precursor layer having a thickness of about 3 μm. A carbon-containing organic precursor layer having a thickness of about 3 μm was also formed on the other surface of the tungsten support by repeating the coating process again.

A graphite holder was installed in a horizontal furnace, the graphite holder was filled with B₂O₃ powder as a boron source, and the tungsten support with the carbon-containing organic precursor layers formed on both surfaces thereof was mounted thereon.

While maintaining the flow rate of a nitrogen gas as a nitrogen-atom source to be about 2 L/min, the temperature of the furnace was raised from 30° C. to 1600° C. at a heating rate of 5° C./min, and the furnace was maintained at about 1600° C. for about 5 hours. The pressure of the furnace was maintained at 1.013×10⁵ Pa (atmospheric pressure). As such, the carbon-containing organic precursor layers were converted into BN layers.

After forming the BN layers, the furnace was cooled down from 1600° C. to 30° C. at a cooling rate of 5° C./min, a heat dissipation layer including the tungsten support with the BN layers on both of the opposite surfaces thereof was taken out of the furnace, and, to analyze properties of the BN layers, Raman spectroscopy analysis and SEM analysis were conducted.

As a result of laser Raman spectroscopy analysis of a surface of the BN layers, a characteristic h-BN peak of the hexagonal BN layer may be observed at a Raman shift position of about 1365 cm⁻¹.

As a result of SEM analysis of the BN layers, it is confirmed that grain boundaries with a size of several micrometers were formed.

Subsequently, a polyvinylidene fluoride film was attached to one surface of the heat dissipation layer including the tungsten support with the BN layers on both of the opposite surfaces thereof by an adhesive layer therebetween and then compressed to form a fluorinated film protective layer.

### EXAMPLE 10

A molybdenum support having a thickness of about 10 μm to about 100 μm and a square shape with a size of about 1 inch× about 1 inch was washed with acetone, IPA, and deionized water in this order each for 5 minutes.

A PMMA resist (manufacturer: MicroChem, Product Name: NANO™ PMMA) was dripped onto a surface of the washed molybdenum support and then spin-coated at a rotating speed of about 4000 rpm for about 60 seconds, followed by drying at a temperature of about 170° C. for about 30 minutes, to form a PMMA layer having a thickness of about 100 nm to about 200 nm. A PMMA layer having a thickness of about 100 nm to about 200 nm was also formed on the other surface of the molybdenum support by repeating the coating process again.

A graphite holder was installed in a horizontal furnace, the graphite holder was filled with B₂O₃ powder as a boron source, and the molybdenum support with the PMMA layer formed on both surfaces thereof was mounted thereon.

While maintaining the flow rate of a nitrogen gas as a nitrogen atom source to be about 2 L/min, the temperature of the furnace was raised from 30° C. to 1600° C. at a heating rate of 5° C./min, and the furnace was maintained at about 1600° C. for about 5 hours. The pressure of the furnace was maintained at 1.013×10⁵ Pa (atmospheric pressure). As such, the PMMA layers were converted into BN layers.

After forming the BN layers, the furnace was cooled down from 1600° C. to 30° C. at a cooling rate of 5° C./min, a heat dissipation layer including the molybdenum support with the BN layers on both of the opposite surfaces thereof was taken out of the furnace, and, to analyze properties of the BN layers, Raman spectroscopy analysis and SEM analysis were conducted.

Subsequently, a polyvinylidene fluoride film was attached to one surface of the heat dissipation layer including the molybdenum support with the BN layers on both of the opposite surfaces thereof by an adhesive layer therebetween and then compressed to form a fluorinated film protective layer.

### EXAMPLE 11

A tungsten support having a thickness of about 10 μm to about 100 μm and a square shape with a size of about 1 inch× about 1 inch was washed with acetone, IPA, and deionized water in this order each for 5 minutes.

A suspension prepared by suspending graphene oxide (GO), which was prepared by using a well-known method, in water was spray-coated onto a surface of the tungsten support at a temperature ranging from 100° C. to 150° C. and a spray rate of about 1 nm/min to form a GO layer having a thickness of about 1 nm to about 10 nm on the tungsten support. A GO layer having a thickness of about 1 nm to about 10 nm was also formed on the other surface of the tungsten support by repeating the coating process again.

A graphite holder was installed in a vertical furnace, the graphite holder was filled with B₂O₃ powder as a boron source, and the tungsten support with the GO layers formed on both surfaces thereof was mounted thereon.

While maintaining the flow rate of a nitrogen gas as a nitrogen atom source to be about 2 L/min, the temperature of the furnace was raised from 30° C. to 1600° C. at a heating rate of 5° C./min, and the furnace was maintained at about 1600° C. for about 5 hours. The pressure of the furnace was maintained at 1.013×10⁵ Pa (atmospheric pressure). As such, the GO layers were converted into BN layers.

After forming the BN layers, the furnace was cooled down from 1600° C. to 30° C. at a cooling rate of 5° C./min, a heat dissipation layer including the tungsten support with the BN layers on both of the opposite surfaces thereof was taken out of the furnace, and, to analyze properties of the BN layers, Raman spectroscopy analysis and SEM analysis were conducted.

Subsequently, an ethylene vinylacetate (EVA) film was attached to one surface of the heat dissipation layer including the tungsten support with the BN layers on both of the opposite surfaces thereof by an adhesive layer therebetween and then compressed to form an EVA film protective layer.

### EXAMPLE 12

A molybdenum support having a thickness of about 10 μm to about 100 μm and a square shape with a size of about 1 inch× about 1 inch was washed with acetone, IPA, and deionized water in this order each for 5 minutes.

Using graphite (Manufacturer: Taewon Science, Product Name: Graphite Target) as a raw material, plasma-enhanced reactive magnetron sputtering was carried out to form a graphite layer having a thickness of about 10 nm to about 1 μm on a surface of the molybdenum support under the following conditions for about 10 minutes to about 60 minutes: operating voltage of 400 V, operating electrical current of 300 mA, Ar flow rate of 50 sccm, and chamber pressure of 210 mTorr. A graphite layer having a thickness of about 1 nm to about 10 nm was also formed on the other surface of the tungsten support by repeating the coating process again.

A graphite holder was installed in a vertical furnace, the graphite holder was filled with B₂O₃ powder as a boron source, and the molybdenum support with the graphite layers formed on both surfaces thereof was mounted thereon.

While maintaining the flow rate of a nitrogen gas as a nitrogen atom source to be about 2 L/min, the temperature of the furnace was raised from 30° C. to 1600° C. at a heating rate of 5° C./min, and the furnace was maintained at about 1600° C. for about 5 hours. The pressure of the furnace was maintained at 1.013×10⁵ Pa (atmospheric pressure). As such, the graphite layers were converted into BN layers.

After forming the BN layers, the furnace was cooled down from 1600° C. to 30° C. at a cooling rate of 5° C./min, a heat dissipation layer including the molybdenum support with the BN layers on both of the opposite surfaces thereof was taken out of the furnace, and, to analyze properties of the BN layers, Raman spectroscopy analysis and SEM analysis were conducted.

Subsequently, an EVA film was attached to one surface of the heat dissipation layer including the molybdenum support with the BN layers formed on both of the opposite surfaces thereof by an adhesive layer therebetween and then compressed to form an EVA film protective layer.

As is apparent from the foregoing description, a carbon-containing organic precursor layer or a carbon-containing inorganic precursor layer is formed on a heat-absorbing support using a coating process, such as spin coating, spray coating or dip coating, or using a vapor deposition method, respectively, that are commonly used in a general semiconductor manufacturing process and, thereafter, the layer is heat-treated in a horizontal or vertical electric furnace at a high temperature under certain conditions so that the layer is easily converted into a BN heat dissipation layer with high quality. Thus, a high-efficiency heat radiation sheet may be easily mass-produced using a simple manufacturing process.

In a heat radiation sheet according to an exemplary embodiment, a heat-absorbing layer and a BN heat dissipation layer are formed such that the layers each independently have high thermal conductivity but different thermal conductivities. In this regard, the heat-absorbing support formed using a metal plate, film or foil, and the like with high heat absorbing capacity first absorbs heat rapidly and then the BN heat dissipation layer formed on at least one of upper and lower surfaces of the heat-absorbing support may rapidly radiate the absorbed heat both, to the outside, in a horizontal direction and in a vertical direction due to its high thermal conductivity.

In the manufacture of the heat radiation sheet, a BN layer is formed by heat-treating a carbon-containing organic or inorganic precursor layer strongly adhered to the heat-absorbing support and thus adhesive strength between the two layers is strong and BN constituting the BN layer has high crystal quality and high strength and thus imparts high durability.

In addition, the heat radiation sheet manufactured using the method described above may be applied to various electronic devices, optical devices, energy-related devices, and the like due to including a generally flexible metal plate, film or foil and a BN heat dissipation layer formed on at least one of upper and lower surfaces thereof.

In addition, according to an exemplary embodiment, a carbon-containing organic precursor pattern layer or a carbon-containing inorganic precursor pattern layer is formed on an inorganic support, such as sapphire (Al₂O₃) support, by using a coating process, such as spin coating, spray coating or dip coating, and by a photolithographic process, respectively, that are commonly used in a general semiconductor manufacturing process and, thereafter, the pattern layer is heat-treated in a horizontal or vertical electric furnace at a high temperature under certain conditions so that the pattern layer is easily converted into a BN heat dissipation pattern layer with high quality. In addition, BN has very high thermal conductivity. Thus, according to an exemplary embodiment, a substrate including the heat dissipation pattern layer that may enhance luminous characteristics of a light emitting device may be easily mass-produced using a simple manufacturing process.

In the light emitting device having the structure described above, the BN heat dissipation pattern layer with high thermal conductivity is formed between an inorganic support and an element constituting the light emitting device, e.g., a first conductive type semiconductor layer such as gallium nitride (GaN) layer, whereby the light emitting device has small volume and heat generated therefrom may be rapidly radiated to the outside. Thus, the light emitting device exhibits an enhanced heat radiation efficiency and a crystal quality, which results in enhanced optical characteristics. In addition, it is expected that the light emitting device has longer operating lifespan.

In addition, in a back sheet for a photovoltaic module according to an exemplary embodiment, instead of forming an adhesive layer on an upper or lower surface of a metal layer with high thermal conductivity, a BN layer with electrically insulating properties and high heat radiation performance both in a horizontal direction and in a vertical direction is closely attached to a metal layer. The metal layer and the BN layer are formed such that the layers each independently have high thermal conductivity but have different thermal conductivities. In this regard, the metal layer with high heat absorbing capacity first absorbs heat rapidly and then the BN layer formed on at least one of upper and lower surfaces of the metal layer may rapidly radiate the absorbed heat both in a horizontal direction and in a vertical direction due to its high thermal conductivity.

In the manufacture of the back sheet, the BN layer is formed by heat-treating a carbon-containing organic or inorganic precursor layer strongly adhered to the metal layer and thus adhesive strength between the two layers is strong without forming an adhesive layer therebetween, and BN constituting the BN layer has high crystal quality and high strength and thus may impart high durability. Thus, the back sheet generally exhibits electrically insulating characteristics, high heat radiation performance both in a horizontal direction and in a vertical direction, and high durability. Since the back sheet has excellent heat radiation characteristics, performance degradation of a photovoltaic module due to heating by direct sunlight and waste heat generated during photovoltaic conversion may be effectively prevented for a long period of time.

In the manufacture of the back sheet, a carbon-containing organic or inorganic precursor layer is formed on a metal layer by using a coating process, such as spin coating, spray coating or dip coating, or by a vapor deposition, which are commonly used in a general semiconductor manufacturing process and, thereafter, the precursor layer is heat-treated in a horizontal or vertical electric furnace at a high temperature under certain conditions so that the precursor layer is easily converted into a BN layer with high quality. Thus, a back sheet for a photovoltaic module that has high heat radiation performance may be easily mass-produced using a simple manufacturing process.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope of the inventive concept as defined by the following claims.

What is claimed is:

1. A heat radiation sheet comprising:
a heat-absorbing support; and
a heat dissipation layer formed on at least one surface of the heat-absorbing support and comprising a boron nitride (BN) layer.

2. The heat radiation sheet of claim 1, wherein the heat-absorbing support comprises a material selected from the group consisting of a metal, a metal oxide, a metal nitride, a metal carbide, and a carbonaceous material.

3. The heat radiation sheet of claim 1, wherein the heat-absorbing support is in the form of a plate, a wafer, a film, or a mesh.

4. A substrate for a light emitting device, comprising:
an inorganic support; and
a BN pattern layer formed on the inorganic support.

5. The substrate of claim 4, wherein the inorganic support comprises a material selected from sapphire (Al₂O₃), silicon (Si), silicon carbide (SiC), gallium nitride (GaN), germanium (Ge), gallium arsenide (GaAs), zinc oxide (ZnO), silicon germanium (SiGe), gallium oxide (Ga₂O₃), lithium gallium oxide (LiGaO₂), lithium aluminum oxide (LiAlO₂), and magnesium aluminum oxide (MgAl₂O₄).

6. The substrate of claim 4, wherein an area ratio of the BN pattern layer to the inorganic substrate is in a range of about 20% to about 80%.

7. A light emitting device comprising:
a substrate comprising an inorganic support and a BN pattern layer formed on the inorganic support;
a first conductive type semiconductor layer formed on the BN pattern layer;
an active layer formed on the first conductive type semiconductor layer;
a second conductive type semiconductor layer formed on the active layer;
a first electrode formed on the first conductive type semiconductor layer; and
a second electrode formed on the second conductive type semiconductor layer.

8. The light emitting device of claim 7, wherein the first conductive type semiconductor layer is an n-type semiconductor layer, and the second conductive type semiconductor layer is a p-type semiconductor layer.

9. The light emitting device of claim 7, further comprising a buffer layer to cover and planarize the BN pattern layer.

10. The light emitting device of claim 7, wherein the inorganic support comprises a material selected from sapphire (Al₂O₃), Si, SiC, GaN, Ge, GaAs, ZnO, SiGe, Ga₂O₃, LiGaO₂, LiAlO₂, and MgAl₂O₄.

11. The light emitting device of claim 7, wherein an area ratio of the BN pattern layer to the inorganic support is in a range of about 20% to about 80%.

12. The light emitting device of claim 7, wherein the inorganic support is a sapphire (Al₂O₃) support, the first conductive type semiconductor layer is an n-type GaN layer, and the second conductive type semiconductor layer is a p-type GaN layer.

13. The light emitting device of claim 7, further comprising an ohmic contact layer formed on the second conductive type semiconductor layer, wherein the second electrode is formed on a partial area of the ohmic contact layer.

14. A light emitting package comprising:
a printed circuit board;
the light emitting device according to claim 7 mounted on the printed circuit board; and
an encapsulation member to encapsulate the light emitting device.

15. A back sheet for a photovoltaic module, comprising:
a heat dissipation layer comprising a metal layer, a first BN layer formed on a lower surface of the metal layer, and a second BN layer formed on an upper surface of the metal layer;
a protective layer formed on one surface of the heat dissipation layer; and
an adhesive layer to adhere the protective layer to the heat dissipation layer.

16. The back sheet of claim 15, wherein the metal layer comprises a material selected from tungsten, titanium, iron, copper, nickel, silver, zinc, molybdenum, and an alloy comprising at least one of these metals.

17. The back sheet of claim 15, wherein the protective layer comprises a film selected from the group consisting of a fluorinated resin film, a polyester film, a polyolefin film, and a polyolefin-based copolymer film.

18. A photovoltaic module comprising:
a photovoltaic cell;
upper and lower encapsulation layers respectively attached to upper and lower surfaces of the photovoltaic cell; and
an upper surface layer attached to the upper encapsulation layer and a back sheet attached to the lower encapsulation layer,
wherein the back sheet comprises:
a heat dissipation layer comprising a metal layer, a first BN layer formed on a lower surface of the metal layer, and a second BN layer formed on an upper surface of the metal layer;
a protective layer formed on one surface of the heat dissipation layer; and
an adhesive layer to adhere the protective layer to the heat dissipation layer.

19. The photovoltaic module of claim 18, wherein the metal layer comprises a material selected from the group consisting of tungsten, titanium, iron, copper, nickel, silver, zinc, molybdenum, and an alloy comprising at least one of these metals.

20. The photovoltaic module of claim 18, wherein the protective layer comprises a film selected from the group consisting of a fluorinated resin film, a polyester film, a polyolefin film, and a polyolefin-based copolymer film.
